(19) United States
(12) Patent Application Publication
(10) Pub. No.: US 2006/0244373 A1
(43) Pub. Date: Nov. 2, 2006

(54) Light emitting device and method for manufacturing thereof

(75) Inventors: Ryoji Nomura, Kanagawa (JP); Kaoru Kato, Kanagawa (JP); Satoshi Yoshimoto, Kanagawa (JP); Shunpei Yamazaki, Tokyo (JP)

Correspondence Address: COOK, ALEX, McFARRON, MANZO,;CUMMINGS & MEHLER, LTD., SUITE 2850, 200 WEST ADAMS STREET, CHICAGO, IL, 60606, US

(73) Assignee: Semiconductor Energy Laboratory Co., Ltd.

(21) Appl. No.: 11/408,216

(22) Filed: Apr. 20, 2006

(30) Foreign Application Priority Data
Apr. 28, 2005 (JP) 2005-130956

(51) Int. Cl. H01L 51/52; H01L 51/56; H05B 33/12

(52) U.S. Cl. 313/506; 313/504; 428/917; 428/212; 428/213; 428/215; 427/66; 445/11

(57) ABSTRACT

An object of the present invention is to provide a light emitting device including an organic light emitting layer and an organic compound and having high light emitting efficient along with less deterioration in characteristics. In the light emitting device, an anode, a cathode facing the anode, light emitting layers each comprising an organic compound and being provided between the anode and the cathode, and carrier transporting layers each comprising an organic compound, are provided over a substrate. Each of the light emitting layers and each of the carrier transporting layers are alternately stacked. A thickness of each of the carrier transporting layers is thinner than that of each of the light emitting layers. When each of the carrier transporting layers is a hole transporting layer, each of the light emitting layers has an electron transporting property. When each of the carrier transporting layers is an electron transporting layer, each of the light emitting layers has a hole transporting property.

### BACKGROUND OF THE INVENTION

1. Field of the Invention

The present invention relates to a light emitting device used for a display and the like, and a method for manufacturing thereof.

2. Description of the Related Art

In recent years, with advance of an information society, needs of a display device, which requires lesser power and is thinner than a conventional CRT, have been increased. As such the display, a liquid crystal display and a plasma display can be given, and these displays have already been put to practical use.

In these days, development of a light emitting device utilizing an organic compound has been carried out so as to realize more reduction in power consumption and more vivid full-colors than the liquid crystal display and the plasma display. In this light emitting device, electrodes (an anode and a cathode) are attached to both surfaces of a solid thin film formed using an organic compound, which emits strong fluorescence or phosphorescence in a solid state. By injecting holes from the anode and injecting electrons from the cathode, the holes and the electrons are recombined in the organic compound to produce an excited state of the organic compound. When the excited state returns to a ground state, the organic compound emits light with a wavelength, which is the same as fluorescence or phosphorescence.

As a structure of the light emitting device, a light emitting device including a single layer structure in which a single organic compound layer plays three roles of transfer of holes, transfer of electrons, and recombination of holes and electrons; a light emitting device including a two layered structure or a three layered structure in which the three roles are divided in two or three layers; and the like have been reported. For example, a light emitting device including a hole transporting layer, a light emitting layer, and an electron transporting layer can be given.

However, there are problems that the reported light emitting devices have low light emitting efficiency and cannot be put to practical use. In order to solve these problems, the patent document 1 proposes a light emitting device having a superlattice structure in which an organic light emitting layer and an inorganic compound layer are alternately stacked.

[Patent Document 1]: Japanese Patent Application Laid-Open No. Hei 8-102360

The organic light emitting layer and the inorganic compound layer are alternately stacked in the light emitting device disclosed in the patent document 1, and therefore, there is a probability of deteriorating a characteristic due to stress.

### SUMMARY OF THE INVENTION

In view of the above problems, it is an object of the present invention to provide a light emitting device having a multistacked structure including an organic light emitting layer and a carrier transporting layer made from an organic compound so that high light emitting efficiency and less deterioration in characteristics are realized.

In an aspect of the present invention, a light emitting device has a structure in which each of light emitting layers comprising an organic compound and each of carrier transporting layers comprising an organic compound are alternately stacked. Specifically, the light emitting device has a structure, in which an electrode, . . . , a light emitting layer, a carrier transporting layer, a light emitting layer, a carrier transporting layer, a light emitting layer, a carrier transporting layer, . . . , and the other electrode are stacked. Further, 2 to n (n is a positive integer) pieces of carrier transporting layers and light emitting layers can alternately be stacked. For example, the following stacked structures can be given: a stacked structure 1, in which an anode, a hole transporting layer, a light emitting layer, a hole transporting layer, a light emitting layer, a hole transporting layer, a light emitting layer, a hole transporting layer, . . . , a light emitting layer, an electron transporting layer, and a cathode are stacked; a stacked structure 2, in which an anode, a first hole transporting layer, a light emitting layer, a second hole transporting layer, a light emitting layer, a second hole transporting layer, a light emitting layer, a second hole transporting layer, . . . , a light emitting layer, an electron transporting layer, and a cathode are stacked; a stacked structure 3, in which an anode, a hole transporting layer, a light emitting layer, an electron transporting layer, a light emitting layer, an electron transporting layer, a light emitting layer, an electron transporting layer, . . . , a light emitting layer, an electron transporting layer, and a cathode are stacked; and a stacked structure 4, in which an anode, a hole transporting layer, a light emitting layer, a second electron transporting layer, a light emitting layer, another second electron transporting layer, a light emitting layer, still another second electron transporting layer, . . . , a light emitting layer, a first electron transporting layer, and a cathode are stacked. As a structure in the vicinity of an anode, a structure A, in which an anode, a hole injecting layer, and a hole transporting layer are stacked; or a structure B, in which an anode, a hole injecting layer, and a first hole transporting layer are stacked, can be used. As a structure in the vicinity of a cathode, a structure C, in which an electron transporting layer, an electron injecting layer, and a cathode are stacked; or a structure D, in which a first electron transporting layer, an electron injecting layer, and a cathode are stacked, may be employed. In the above mentioned stacked structure 2, in a case where the first hole transporting layer and the second hole transporting layers are formed using the same material, this stacked structure 2 becomes the same as the stacked structure 1. In the stacked structure 4, in a case where the first electron transporting layer and the second electron transporting layers are formed using the same material, the stacked structure 4 becomes the same as the stacked structure 3.

In the present invention, the carrier transporting layers may be either hole transporting layers or electron transporting layers. However, in a case where the light emitting layers have an electron transporting property, the carrier transporting layers are hole transporting layers. On the other hand, in a case where the light emitting layers have a hole transporting property, the carrier transporting layers are electron transporting layers.

In the light emitting device of the present invention, a thickness of each of the carrier transporting layers is thinner than a thickness of a light emitting layer. Each of the carrier transporting layers preferably has 1 to 5 nm in thickness. Each of the light emitting layers preferably has 5 to 20 nm in thickness. Accordingly, carriers can be transferred in accordance with a tunnel effect.

In the present invention, in a case where the carrier transporting layers are hole transporting layers (i.e., in the case of the above mentioned stacked structure 1), an absolute value of an energy difference between a LUMO level of each of the light emitting layers and a vacuum level is preferably larger than an absolute value of an energy difference between a LUMO level of each of the hole transporting layers and the vacuum level (i.e., the LUMO level of each of the light emitting layers is lower than the LUMO level of each of the hole transporting layers), and an absolute value of an energy difference between a HOMO level of each of the light emitting layers and the vacuum level is preferably larger than an absolute value of an energy difference between a HOMO level of each of the hole transporting layers and the vacuum level (i.e., the HOMO level of each of the light emitting layers is lower than the HOMO level of each of the hole transporting layers). Note that, the LUMO indicates lowest unoccupied molecular orbital whereas the HOMO indicates highest occupied molecular orbital.

Meanwhile, in a case where the carrier transporting layers are electron transporting layers (i.e., in the case of the above mentioned stacked structure 3), an absolute value of an energy difference between a LUMO level of each of the light emitting layers and a vacuum value is preferably smaller than an absolute value of an energy difference between a LUMO level of each of the electron transporting layers and the vacuum level (i.e., the LUMO level of each of the light emitting layers is higher than the LUMO level of each of the electron transporting layers), and an absolute value of an energy difference between a HOMO level of each of the light emitting layers and the vacuum level is preferably smaller than an absolute value of an energy difference between a HOMO level of each of the electron transporting layers and the vacuum level (i.e., the HOMO level of each of the light emitting layers is higher than the HOMO level of each of the electron transporting layers).

In the case of the stacked structure 2, an absolute value of an energy difference between a LUMO level of each of the light emitting layers and a vacuum level is preferably larger than an absolute value of an energy difference between a LUMO level of each of the second hole transporting layers and the vacuum level (i.e., the LUMO level of each of the light emitting layers is lower than the LUMO level of each of the second hole transporting layers), and an absolute value of an energy difference between a HOMO level of each of the light emitting layers and the vacuum level is preferably larger than an absolute value of an energy difference between a HOMO level of each of the second hole transporting layers and the vacuum level (i.e., the HOMO level of each of the light emitting layers is lower than the HOMO level of each of the second hole transporting layers).

Further, an absolute value of an energy difference between a HOMO level of the first hole transporting layer and the HOMO level of each of the light emitting layers is preferably smaller than an absolute value of the energy difference between the HOMO level of each of the second hole transporting layers and the HOMO level of each of the light emitting layers.

Furthermore, an absolute value of an energy difference between work function of the anode and the HOMO level of the first hole transporting layer is preferably smaller than an absolute value of the energy difference between the HOMO level of each of the second hole transporting layers and the HOMO level of each of the light emitting layers.

In the case of the stacked structure 4, an absolute value of an energy difference between a LUMO level of each of the light emitting layers and a vacuum level is preferably smaller than an absolute value of an energy difference between a LUMO level of each of the second electron transporting layers and the vacuum level (i.e., the LUMO level of each of the light emitting layers is higher than the LUMO level of each of the second electron transporting layers), and an absolute value of an energy difference between a HOMO level of each of the light emitting layers and the vacuum level is preferably smaller than an absolute value of an energy difference between a HOMO level of each of the second electron transporting layers and the vacuum level (i.e., the HOMO level of each of the light emitting layers is higher than the HOMO level of each of the second electron transporting layers).

An absolute value of an energy difference between the LUMO level of the first electron transporting layer and the LUMO level of each of the light emitting layers is preferably smaller than an absolute value of an energy difference between the LUMO level of each of the second electron transporting layers and the LUMO level of each of the light emitting layers.

Further, an absolute value of an energy difference between work function of the cathode and the LUMO level of the first electron transporting layer is preferably smaller than an absolute value of the energy difference between the LUMO level of each of the second electron transporting layers and the LUMO level of each of the light emitting layers.

In the present invention, a multistacked structure can be formed by co-evaporation of a light emitting material including an organic compound and a carrier transporting material including an organic compound. In forming the above mentioned multistacked structure, thicknesses of a light emitting layer and a carrier transporting layer can be controlled by providing a shutter or a mask and by closing and opening the shutter or the mask.

For example, shutters or masks are provided between an evaporation source of a light emitting material and a substrate, which is a target matter, and between an evaporation source of a carrier transporting material and the substrate so that the thicknesses of a light emitting layer and a carrier transporting layer are controlled by opening and closing the shutters or the masks. When the shutter is opened or the mask is not provided, the light emitting material or the carrier transporting material is evaporated over the substrate whereas when the shutter is closed or the mask is provided, the light emitting material or the carrier transporting material is not evaporated over the substrate.

When the shutter or the mask of the evaporation source of the light emitting material is opened and the light emitting material is evaporated over a substrate, the shutter or the mask over the evaporation source of the carrier transporting material is closed such that the carrier transporting material is not evaporated over the substrate. Next, while the shutter or the mask of the evaporation source of the light emitting material is closed such that the light emitting material is not evaporated over the substrate, the shutter or the mask of the evaporation source of the carrier transporting material is opened, and the carrier transporting material is evaporated over the substrate. In such a manner, each of the light emitting layers and each of the carrier transporting layers can be alternately stacked. Note that, in the present invention, since the thickness of each of the carrier transporting layers is necessary to be thinner than that of each of the light emitting layers, opening time and closing time of the shutters or the masks are necessary to be controlled.

A mask may be opened by rotation. Further, a hole or a slit may be provided in a part of a mask.

By changing an evaporation rate of a material filled in an evaporation source while opening and closing a shutter or a mask, a film thickness can be changed. When the evaporation rate is low and opening time of the shutter or the mask is shortened, a film thickness becomes thin. On the other hand, when the evaporation rate is high and closing time of the shutter or mask is lengthened, a film thickness is increased.

A substrate, which is a target matter, may rotate on its axis. When the substrate rotates on its axis, uniformity of a film thickness can be improved.

Further, an evaporation source filled with a light emitting material is fixed away from an evaporation source filled with a carrier transporting material and a substrate is rotated while being moved around a central axis so that evaporation amounts can be changed. Further, the substrate may be rotated by combining the above mentioned rotation methods.

For example, a substrate is provided over a first rotating plate, and the first rotating plate is provided over an evaporation source of a light emitting material and an evaporation source of a carrier transporting material. When a distance between the evaporation source of the light emitting material and the substrate and a distance between the evaporation source of the carrier transporting material and the substrate are changed by rotating the first rotating plate, each of the light emitting layers and each of the carrier transporting layers are alternately stacked.

When the first rotating plate rotates, the distance between the evaporation source of the light emitting material and the substrate and the distance between the evaporation source of the carrier transporting material and the substrate are changed. When the distance between the evaporation source of the light emitting material and the substrate is shorter than the distance between the evaporation source of the carrier transporting material and the substrate, a larger amount of the light emitting material is evaporated over the substrate to form a light emitting layer. On the other hand, when the distance between the evaporation source of the carrier transporting material and the substrate is shorter than the distance between the evaporation source of the light emitting material and the substrate, a larger amount of the carrier transporting material is evaporated over the substrate to form a carrier transporting layer. By changing a position of the substrate with respect to the evaporation sources by rotating the first rotating plate in such a manner, light emitting layers and carrier transporting layers can also be stacked alternately. Thus, a multistacked structure can be realized. Further, the substrate is moved here; however, the evaporation source of the light emitting material and the evaporation source of the carrier transporting material may be moved while fixing the substrate.

Note that, in the present invention, a thickness of a carrier transporting layer is necessary to be thinner than a thickness of a light emitting layer. Therefore, an evaporation rate of a carrier transporting material filled in an evaporation source may be controlled, or, by providing a shutter or a mask between the carrier transporting material and a substrate, opening time and closing time of the shutter or the mask may be controlled.

A second rotating plate, which has a central axis different from a central axis of the first rotating plate and rotates independently of the first rotating plate, may be provided over the first rotating plate, and a substrate may be provided over the second rotating plate. The uniformity of a film thickness over the substrate may be improved by rotating the second rotating plate (i.e., by rotating the substrate on its axis).

Further, in the present invention, a buffer layer including an organic compound and a metal compound may be provided between an electrode and a carrier transporting layer. This can improve flatness. Specifically, a buffer layer may be provided between an anode and a hole transporting layer, between an anode and a first hole transporting layer, between an electron transporting layer and a cathode, or between a first electron transporting layer and a cathode. In this case, a hole injecting layer and an electron injecting layer may also be provided as described above.

In another aspect of the present invention, a light emitting device has an anode, a cathode facing the anode, light emitting layers each comprising an organic compound, which is provided between the anode and the cathode, and carrier transporting layers each comprising an organic compound, over a substrate. Each of the light emitting layers and each of the carrier transporting layers are alternately stacked. A thickness of each of the carrier transporting layers is thinner than that of each of the light emitting layers. In a case where each of the carrier transporting layers is a hole transporting layer, each of the light emitting layers has an electron transporting property. In a case where each of the carrier transporting layers is an electron transporting layer, each of the light emitting layers has a hole transporting property.

Further, 2 to n (n is a positive integer) pieces of the light emitting layers and the carrier transporting layers are alternately stacked.

A thickness of each of the carrier transporting layers is 1 to 5 nm, and a thickness of each of the light emitting layers is 5 to 20 nm.

The carrier transporting layers may be hole transporting layers. An absolute value of an energy difference between a LUMO level of each of the light emitting layers and a vacuum level may be larger than an absolute value of an energy difference between a LUMO level of each of the hole transporting layers and the vacuum level, and an absolute value of an energy difference between a HOMO level of the light emitting layer and the vacuum level may be larger than an absolute value of an energy difference between a HOMO level of each of the hole transporting layers and the vacuum level.

In the case where the carrier transporting layers are the hole transporting layers, the LUMO level of each of the light emitting layers may be lower than the LUMO level of each of the hole transporting layers, and the HOMO level of each of the light emitting layers may be lower than the HOMO level of each of the hole transporting layers.

Alternatively, the carrier transporting layers may be electron transporting layers. An absolute value of an energy difference between a LUMO level of each of the light emitting layers and a vacuum value may be smaller than an absolute value of an energy difference between a LUMO level of each of the electron transporting layers and the vacuum level, and an absolute value of an energy difference between a HOMO level of each of the light emitting layers and the vacuum level is preferably smaller than an absolute value of an energy difference between a HOMO level of each of the electron transporting layers and the vacuum level.

In the case where the carrier transporting layers are the electron transporting layers, the LUMO level of each of the light emitting layers may be higher than the LUMO level of each of the electron transporting layers, and the HOMO level of each of the light emitting layers may be higher than the HOMO level of each of the electron transporting layers.

A buffer layer including an organic compound and a metal compound may be provided to be in contact with the anode.

In another aspect of the present invention, a light emitting device includes an anode, a cathode facing the anode, light emitting layers each comprising an organic compound, which is provided between the anode and the cathode, a first carrier transporting layer including an organic compound, and second carrier transporting layers each comprising an organic compound, over a substrate. The first carrier transporting layer is provided between the anode and the light emitting layer or the cathode and the light emitting layer. Each of the light emitting layers and each of the second carrier transporting layers are alternately stacked. A thickness of each of the second carrier transporting layers is thinner than that of each of the light emitting layers. In a case where the first and second carrier transporting layers are hole transporting layers, the light emitting layer has an electron transporting property. In a case where the first and second carrier transporting layers are electron transporting layers, the light emitting layer has a hole transporting property.

Further, 2 to n (n is a positive integer) pieces of the light emitting layers and the second carrier transporting layers are alternately stacked.

A thickness of each of the second carrier transporting layers is 1 to 5 nm, and a thickness of each of the light emitting layers is 5 to 20 nm.

Both of the first and second carrier transporting layers may be hole transporting layers. In this case, an absolute value of an energy difference between a LUMO level of each of the light emitting layers and a vacuum level may be larger than an absolute value of an energy difference between a LUMO level of each of the second carrier transporting layers and the vacuum level, and an absolute value of an energy difference between a HOMO level of each of the light emitting layers and the vacuum level may be larger than an absolute value of an energy difference between a HOMO level of each of the second carrier transporting layers and the vacuum level.

In the case where both of the first and second carrier transporting layers are the hole transporting layers, the LUMO level of each of the light emitting layers may be lower than the LUMO level of each of the second carrier transporting layers and the HOMO level of each of the light emitting layers may be lower than the HOMO level of each of the second carrier transporting layers.

In the case where both of the first and second carrier transporting layers are the hole transporting layers, an absolute value of an energy difference between the HOMO level of the first carrier transporting layer and the HOMO level of each of the light emitting layers may be smaller than an absolute value of an energy difference between the HOMO level of each of the second carrier transporting layers and the HOMO level of each of the light emitting layers.

In the case where both of the first and second carrier transporting layers are the hole transporting layers, an absolute value of an energy difference between work function of the anode and the HOMO level of the first carrier transporting layer may be smaller than an absolute value of an energy difference between the HOMO level of each of the second carrier transporting layers and the HOMO level of each of the light emitting layers.

Both of the first and second carrier transporting layers may be electron transporting layers. In this case, an absolute value of an energy difference between a LUMO level of each of the light emitting layers and a vacuum value may be smaller than an absolute value of an energy difference between a LUMO level of each of the second carrier transporting layers and the vacuum level, and an absolute value of an energy difference between a HOMO level of each of the light emitting layers and the vacuum level is preferably smaller than an absolute value of an energy difference between a HOMO level of each of the second carrier transporting layers and the vacuum level.

In the case where both of the first and second carrier transporting layers are the electron transporting layers, the LUMO level of each of the light emitting layers may be higher than the LUMO level of each of the second carrier transporting layers, and the HOMO level of each of the light emitting layers may be higher than the HOMO level of each of the second carrier transporting layers.

In the case where both of the first and second carrier transporting layers are the electron transporting layers, an absolute value of an energy difference between the LUMO level of the first carrier transporting layer and the LUMO level of each of the light emitting layers may be smaller than an absolute value of an energy difference between the LUMO level of each of the second carrier transporting layers and the LUMO level of each of the light emitting layers.

In the case where both of the first and second carrier transporting layers are the electron transporting layers, an absolute value of an energy difference between work function of the cathode and the LUMO level of the first carrier transporting layer may be smaller than an absolute value of an energy difference between the LUMO level of each of the second carrier transporting layers and the LUMO level of each of the light emitting layers.

A buffer layer including an organic compound and a metal compound may be provided between the first carrier transporting layer and the anode or the cathode.

In another aspect of the present invention, a method for manufacturing a light emitting device, which has an anode, a cathode facing the anode, light emitting layers each comprising an organic compound, which is provided between the anode and the cathode, and carrier transporting layers each comprising an organic compound, over a substrate, is provided, wherein each of the light emitting layers and each of the carrier transporting layers are alternately stacked, wherein a thickness of each of the carrier transporting layer is thinner than that of each of the light emitting layer, wherein in a case where the carrier transporting layer is a hole transporting layer, the light emitting layer has an electron transporting property, and wherein in a case where the carrier transporting layers is an electron transporting layer, the light emitting layer has a hole transporting property. The substrate is provided over an evaporation source of a carrier transporting maternal and an evaporation source of a light emitting material. A first shutter, which is openable and closable, is provided between the evaporation source of the carrier transporting material and the substrate. A second shutter, which is openable and closable, is provided between the evaporation source of the light emitting material and the substrate. Each of the light emitting layers and each of the carrier transporting layers are alternately stacked by opening and closing the first and second shutters.

When the first shutter is opened while the second shutter is closed, the carrier transporting material is evaporated over the substrate. When the second shutter is opened while the first shutter is closed, the light emitting material is evaporated over the substrate. In such a manner, the light emitting layer and the carrier transporting layer may be alternately stacked.

By controlling opening and closing of the shutters, an evaporation rate of the light emitting material, and an evaporation rate of the carrier transporting material, each of the light emitting layer and each of the carrier transporting layer may be alternately stacked.

In another aspect of the present invention, a method for manufacturing a light emitting device, which has an anode, a cathode facing the anode, light emitting layers each comprising an organic compound, which is provided between the anode and the cathode, and carrier transporting layers each comprising an organic compound, over a substrate, is provided, wherein each of the light emitting layers and each of the carrier transporting layers are alternately stacked, wherein a thickness of each of the carrier transporting layers is thinner than that of each of the light emitting layers, wherein in a case where each of the carrier transporting layers is a hole transporting layer, each of the light emitting layers has an electron transporting property, and wherein in a case where each of the carrier transporting layers is an electron transporting layer, each of the light emitting layers has a hole transporting property. The substrate is provided over a first rotating plate, and the first rotating plate is provided over an evaporation source of a light emitting material and an evaporation source of a carrier transporting maternal. By rotating the first rotating plate to change a distance between the evaporation source of the light emitting material and the substrate and a distance between the evaporation source of the carrier transporting material and the substrate, each of the light emitting layers and each of the carrier transporting layers are alternately stacked.

When the first rotating plate rotates and the distance between the evaporation source of the light emitting material and the substrate is shorter than the distance between the evaporation source of the carrier transporting material and the substrate, a larger amount of the light emitting material is evaporated over the substrate than the carrier transporting material to form the light emitting layer. When the first rotating plate rotates and the distance between the evaporation source of the carrier transporting material and the substrate is shorter than the distance between the evaporation source of the light emitting material and the substrate, a larger amount of the carrier transporting material is evaporated over the substrate than the light emitting material to form the carrier transporting layer.

By controlling an evaporation rate of the light emitting material and an evaporation rate of the carrier transporting material, each of the light emitting layers and each of the carrier transporting layers may be alternately stacked.

When a shutter, which is openable and closable, is provided between the evaporation source of the carrier transporting material and the substrate, by controlling rotation of the first rotating plate and controlling opening and closing of the shutter, each of the light emitting layers and each of the carrier transporting layers may be alternately stacked.

A second rotating plate may be provided over the first rotating plate, the substrate may be provided over the second rotating plate, the first and second rotating plates may have different central axes from each other, and the first and second rotating plates may be independently rotated.

In another aspect of the present invention, a method for manufacturing a light emitting device, which has an anode, a cathode facing the anode, light emitting layers each comprising an organic compound, which is provided between the anode and the cathode, and carrier transporting layers comprising an organic compound, over a substrate, is provided, wherein each of the light emitting layers and each of the carrier transporting layers are alternately stacked, wherein a thickness of each of the carrier transporting layers is thinner than that of each of the light emitting layers, wherein in a case where each of the carrier transporting layer is a hole transporting layer, each of the light emitting layer has an electron transporting property, and wherein in a case where each of the carrier transporting layers is an electron transporting layer, each of the light emitting layers has a hole transporting property. The substrate is provided over an evaporation source of a carrier transporting maternal and an evaporation source of a light emitting material. A first mask, which is rotatable, is provided between the evaporation source of the light emitting material and the substrate. A second mask, which is rotatable, is provided between the evaporation source of the carrier transporting material and the substrate. By controlling rotation of the first and second masks, each of the light emitting layers and each of the carrier transporting layers are alternately stacked.

A slit or a hole may be provided in each of the first and second masks.

When the hole or the slit of the first mask is positioned between the evaporation source of the light emitting material and the substrate, the hole or the slit of the second mask is not positioned between the evaporation source of the carrier transporting material and the substrate so that the light emitting material may be evaporated over the substrate. Meanwhile, when the hole of silt of the second mask is positioned between the evaporation source of the carrier transporting material and the substrate, the hole or silt of the first mask is not positioned between the evaporation source of the light emitting material and the substrate so that the carrier transporting material may be evaporated over the substrate. Thus, each of the light emitting layers and each of the carrier transporting layers may be alternately stacked.

By controlling an evaporation rate of the light emitting material and an evaporation rate of the carrier transporting material, each of the light emitting layers and each of the carrier transporting layers may be alternately stacked.

The present invention provides a multistacked structure, in which light emitting layers an organic compound and carrier transporting layers including an organic compound are alternately stacked. Since the multistacked structure of the present invention is not a multistacked structure of layers including an organic compound and layers including an inorganic compound, a light emitting device having less deterioration in characteristics and good light emitting efficiency can be obtained without generating stress.

In the present invention, the light emitting layer and the carrier transporting layer have different polarities form each other, a thickness of the carrier transporting layer is thinner than that of the light emitting layer. In addition, the light emitting layer and the carrier transporting layer have the above described LUMO levels and HOMO levels. Accordingly, carriers having the same polarity as the carrier transporting layer can be easily confined, and carriers having different polarity from the carrier transporting layer move by a tunnel effect. That is, either electrons or holes can be confined, and hence, light emitting efficiency can be improved.

Further, by providing a buffer layer including an organic compound and a metal compound between an electrode and the carrier transporting layer, flatness can be improved even if the substrate has concavity and convexity. The thickness of the buffer layer may be set to be 60 nm or more. In the present invention, driving voltage is not increased even though the thickness of the buffer layer is increased.

By implementing the above described manufacturing method, a multistacked structure can be formed. In addition, a light emitting device having less deterioration in characteristic and good light emitting efficiency, in which a film thickness can be easily controlled, can be obtained.

### BRIEF DESCRIPTION OF DRAWINGS

In the accompanying drawings:

FIG. 1 is a diagram explaining a light emitting device of the present invention;

FIG. 2 is a diagram explaining a light emitting device of the present invention;

FIG. 3 is a diagram explaining a light emitting device of the present invention;

FIG. 4 is a diagram explaining a light emitting device of the present invention;

FIG. 5 is a diagram explaining a light emitting device of the present invention;

FIG. 6 is a diagram explaining a light emitting device of the present invention;

FIG. 7 is a diagram explaining a method for manufacturing a light emitting device of the present invention;

FIGS. 8A and 8B are diagrams explaining a method for manufacturing a light emitting device of the present invention;

FIG. 9 is a diagram explaining a method for manufacturing a light emitting device of the present invention;

FIG. 10 is a diagram explaining a method for manufacturing a light emitting device of the present invention;

FIGS. 11A and 11B are diagrams explaining a method for manufacturing a light emitting device of the present invention;

FIGS. 12A and 12B are diagrams explaining a method for manufacturing a light emitting device of the present invention;

FIGS. 13A and 13B are diagrams explaining a method for manufacturing a light emitting device of the present invention;

FIGS. 14A to 14E are cross sectional views explaining a method for manufacturing a TFT;

FIGS. 15A to 15C are cross sectional views explaining a method for manufacturing a light emitting device of the present invention;

FIGS. 16A and 16B are cross sectional views explaining cross sections of a light emitting device of the present invention;

FIG. 17 is a diagram explaining an exterior appearance of a light emitting device of the present invention;

FIG. 18A is a top view and FIG. 18B is a cross sectional view explaining a pixel portion of a light emitting device of the present invention;

FIGS. 19A to 19E are diagrams explaining electronic appliances using light emitting devices of the present invention;

FIGS. 20A and 20B are diagrams explaining electronic appliances using light emitting devices of the present invention;

FIG. 21 is a diagram explaining a light emitting device of the present invention; and

FIG. 22 is a diagram explaining a light emitting device of the present invention.

### DETAILED DESCRIPTION OF THE INVENTION

### Embodiment Mode 1

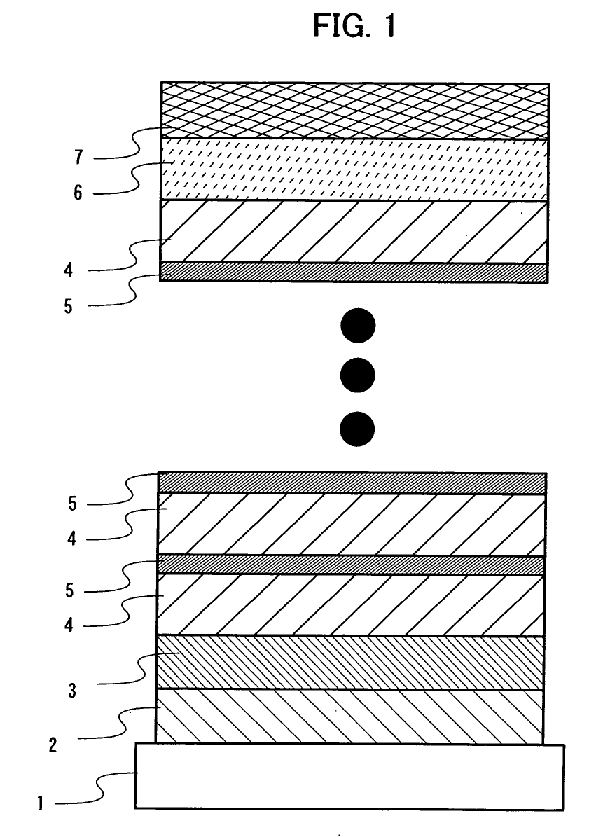

An example of the present invention will be described with reference to FIGS. 1 to 4. A case where the carrier transporting layers are hole transporting layers, will be described here.

In a light emitting device shown in FIG. 1, an anode 2; a first hole transporting layer 3; light emitting layers 4 and second hole transporting layers 5 which are repeatedly stacked; an electron transporting layer 6; and a cathode 7 are formed over a substrate 1. A hole injecting layer may be provided between the anode 2 and the first hole transporting layer 3. Further, an electron injecting layer may be provided between the cathode 7 and the electron transporting layer 6. The first and second hole transporting layers may be formed by using the same material, or different materials. Many layers of the second hole transporting layers 5 and the light emitting layers 4 are stacked. A thickness of each of the second hole transporting layers 5 is thinner than a thickness of each of the light emitting layers 4. The thickness of each of the second hole transporting layers is preferably set to be 1 to 5 nm. The thickness of each of the light emitting layers 4 is preferably set to be 5 to 20 nm. The light emitting layers 4 have an electron transporting property. Further, 2 to n (n is a positive integer) pieces of the second hole transporting layers 5 and the light emitting layers 4 can be alternately stacked.

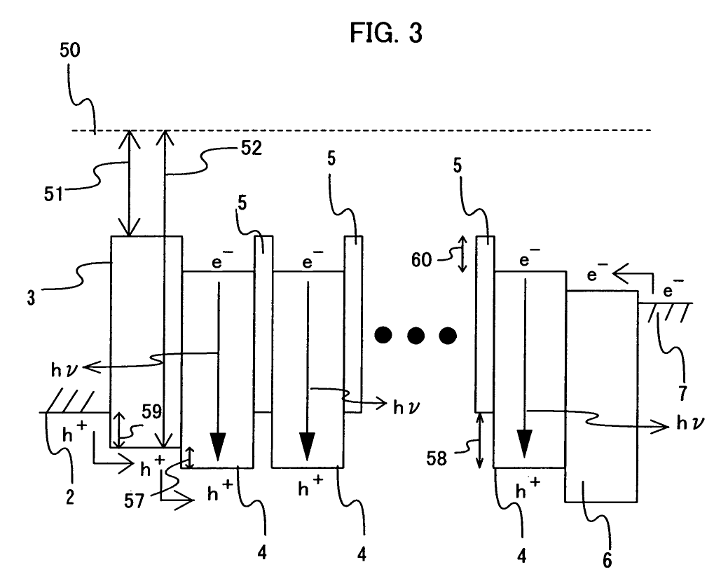

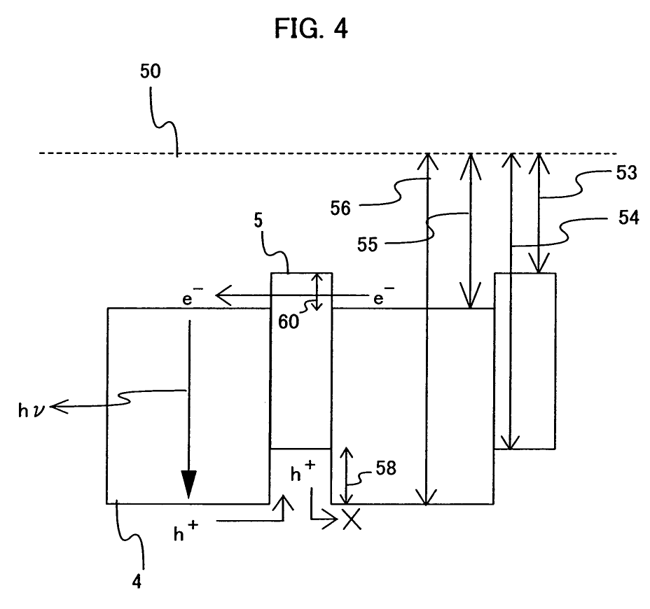

Energy levels, carrier movement, and the like of the present invention will be described here with reference to FIGS. 3 and 4. FIGS. 3 and 4 show band diagrams of the structure of FIG. 1. FIG. 4 shows a band diagram of a multistacked portion of the light emitting layers 4 and the hole transporting layers 5. Reference numerals, which are the same as those of FIG. 1, are used in FIGS. 3 and 4. Reference numeral 50 indicates a vacuum level; and 51, an absolute value of an energy difference between a LUMO level of the first hole transporting layer 3 and the vacuum level 50. Reference numeral 52 indicates an absolute value of an energy difference between a HOMO level of the first hole transporting layer 3 and the vacuum level 50. Reference numeral 53 indicates an absolute value of an energy difference between a LUMO level of each of the second hole transporting layers 5 and the vacuum level 50. Reference numeral 54 indicates an absolute value of an energy difference between a HOMO level of each of the second hole transporting layers 5 and the vacuum level 50. Reference numeral 55 indicates an absolute value of an energy difference between a LUMO level of each of the light emitting layers 4 and the vacuum level 50. Reference numeral 56 indicates an absolute value of an energy difference between a HOMO level of each of the light emitting layers 4 and the vacuum level 50.

In the present invention, the absolute value 55 of the energy difference between the LUMO level of each of the light emitting layers 4 and the vacuum level is larger than the absolute value 53 of the energy difference between the LUMO level of each of the second hole transporting layers 5 and the vacuum level (i.e., the LUMO level of each of the light emitting layers 4 is lower than the LUMO level of each of the second hole transporting layers 5). Further, the absolute value 56 of the energy difference between the HOMO level of each of the light emitting layers 4 and the vacuum level is larger than the absolute value 54 of the energy difference between the HOMO level of each of the second hole transporting layers 5 and the vacuum level (i.e., the HOMO level of each of the light emitting layers 4 is lower than the HOMO level of each of the second hole transporting layers 5).

When positive potential is applied to the anode 2 while negative potential is applied to the cathode 7, holes (h⁺) are injected in the first hole transporting layer 3 from the anode 2 and electrons (e⁻) are injected in the electron transporting layer 6 from the cathode 7. The holes are transported to the light emitting layers 4, which are adjacent to the first hole transporting layer 3, from the first hole transporting layer, and the holes are recombined with the electrons transported from the cathode in the light emitting layers 4. Thus, light is emitted. Since each of the light emitting layers 4 has an electron transporting property, there is a high probability of recombining the holes and electrons. Note that, portions where light is emitted are indicated by hv in the drawings.

Holes, which are not recombined with electrons in the light emitting layer 4, are moved toward the cathode 7 by a potential difference. Subsequently, the holes are injected to the second hole transporting layer 5 and moved inside of the second hole transporting layer 5. However, because of a barrier between each of the second hole transporting layers 5 and each of the light emitting layers 4 (i.e., an energy difference 58, which is an energy difference between the HOMO level of each of the light emitting layers 4 and the HOMO level of each of the second hole transporting layers 5), a probability of injecting holes to each of the light emitting layers 4 is reduced, and therefore, the holes are confined in the second hole transporting layer 5. Even if the holes are injected in one of the light emitting layers 4 beyond the barrier due to accumulation of holes and the like, the holes are recombined with electrons inside of the light emitting layer 4 so that light is emitted. Further, if the holes are not recombined with electrons inside of one of the light emitting layers 4 and are injected in one of the second hole transporting layers 5, there is a high probability of being confined in the second hole transporting layer 5 due to the barrier between the second hole transporting layer 5 and the light emitting layer 4 as described above. Therefore, light emitting efficiency can be improved while preventing holes from passing through the electron transporting layer 6. In a case where the electron transporting layer 6 has a light emitting property, when holes are injected in the electron transporting layer 6, the holes are recombined with electrons in the electron transporting layer and light is emitted. In a case where an emission wavelength of the electron transporting layer 6 is different from an emission wavelength of each of the light emitting layers 4, differences in colors are caused.

On the other hand, electrons, which are not recombined with holes in one of the light emitting layers 4, are moved toward the anode 2 by a potential difference. In this case, since each of the second hole transporting layers 5 has a thin thickness as 1 to 5 nm, the electrons pass through the second hole transporting layer 5 in spite of the existence of a barrier (i.e., an energy difference 60, which is an energy difference between the LUMO level of each of the light emitting layers 4 and the LUMO level of each of the second hole transporting layers 5), and then the holes are injected in the next light emitting layer 4. Thus, the electrons are recombined with holes in the light emitting layer 4 so that light is emitted. Further, even if the electrons are not recombined with holes in the light emitting layer 4, the electrons are injected to the next light emitting layer 4 through the second hole transporting layer 5.

When the first hole transporting layer 3 and the second hole transporting layers 5 are formed using different materials, in order to increase an effect of confining holes, an absolute value of the energy difference 57 between the HOMO level of the first hole transporting layer 3 and the HOMO level of each of the light emitting layers 4 is preferably set to be smaller than an absolute value of the energy difference 58. Accordingly, a probability that holes injected from the anode 2 cannot move beyond the energy difference 58, can be improved.

When an energy difference 59 between work function of the anode 2 and the HOMO level of the first hole transporting layer 3 or potential applied to the anode 2 and the cathode 7 is controlled, the probability that holes cannot move beyond the energy difference 58, can be improved. The energy difference 59 is made smaller than the energy difference 58, and voltage, by which holes move beyond only the energy difference 59, is applied. In this case, the holes can move beyond the energy difference 59; however, the probability of moving beyond the energy difference 58 is reduced. Accordingly, it is preferable to use the anode 2, the first hole transporting layer 3, the light emitting layers 4, the second hole transporting layers 5, and the cathode 7 having the above described relations while controlling voltage applied to the anode and the cathode.

Materials and the like, which can be used for each layer, will be described below. The substrate 1 is used as a supporting body of the light emitting element. As a material of the substrate 1, for example, quartz, glass, plastic, or the like can be used. Note that other material can be used so long as it serves as a supporting body of the light emitting element during manufacturing processes.

As the anode 2, indium tin oxide (ITO) and the like can be used. In addition, indium zinc oxide (IZO), indium tin oxide containing silicon oxide (ITSO), or the like can be used. Further, the anode 2 is preferably formed using a material having high work function.

The first hole transporting layer 3 can be formed using 4,4′-bis[N-(1-naphthyl)-N-phenyl-amino]-biphenyl (abbreviation: NPB or αNPD), 4,4′,4″-tris(N-carbazolyl) triphenylamine (abbreviation: TCTA), and the like can be used. The first hole transporting layer 3 is preferably formed using a material having a HOMO level of −5.3 to −5.6 eV.

The first hole transporting layer 3 and the second hole transporting layers 5 may be formed using the same material. However, in order to improve an effect of confining holes, an energy difference between the HOMO level of the first hole transporting layer 3 and the HOMO level of each of the light emitting layers 4 may be made smaller than an energy difference between the HOMO level of each of the second hole transporting layers 5 and the HOMO level of each of the light emitting layers 4. A material having a HOMO level of −4.9 to −5.3 eV is preferably used. For example, 4,4′,4″-tris[N-(3-methylphenyl)-N-phenyl-amino]-triphenylamine (abbreviation: MTDATA), 4,4′-bis(N-(4-(N,N-di-m-tolylamino)phenyl)-N-phenylamino) biphenyl (abbreviation: DNTPD), 4,4′,4″-tris[N-(1-naphthyl)-N-phenyl-amino]-triphenylamine (abbreviation: 1-TNATA), and the like can be used. For example, when the light emitting layers 4 are formed using the after-mentioned tris(8-quinolinolato)aluminum (abbreviation: Alq₃) and the first hole transporting layer 3 is formed using αNPD, the second hole transporting layers 5 can be formed using MTDATA having the above mentioned relations.

With respect to the light emitting layers 4, an absolute value of an energy difference between a LUMO level of each of the light emitting layers 4 and a vacuum level is necessary to be made larger than an absolute value of an energy difference between a LUMO level of each of the second hole transporting layers 5 and the vacuum level. Further, an absolute value of an energy difference between a HOMO level of each of the light emitting layers 4 and the vacuum level is necessary to be larger than an absolute value of an energy difference between a HOMO level of each of the second hole transporting layers 5 and the vacuum level. This makes it possible to confine holes in the light emitting layers 4 as described above and improve light emitting efficiency. In addition, holes can be prevented from passing through the electron transporting layer 6. On the other hand, since the thickness of each of the second hole transporting layers 5 is thinner than that of each of the light emitting layers 4 and is 1 to 5 nm whereas the thickness of each of the light emitting layers 4 is 5 to 20 nm, electrons are injected in the light emitting layers 4 through the second hole transporting layers 5 even though there are above described energy relations. The light emitting layers 4 can be formed using a material having an electron transporting property such as Alq₃, in addition to a carbazolyl derivative such as 4,4′-di(N-carbazolyl)biphenyl (abbreviation: CBP). A material having a HOMO level of −5.5 to −5.9 eV or more is preferable.

Each of the light emitting layers 4 may be a host-guest type layer in which a light emitting substance (a dopant material), which becomes a light emission center, is dispersed in a layer made from a material (a host material) having a larger energy gap than that of the light emitting substance. This is a preferable structure since light quenching due to a concentration is difficult to be caused. As the light emitting substance, which becomes a light emission center, 4-dicyanomethylene-2-methyl-6-(1,1,7,7-tetramethyljulolidyl-9-enyl)-4H-pyran (abbreviation: DCJT); 4-dicyanomethylene-2-t-buthyl-6-(1,1,7,7-tetramethyljulolidyl-9-enyl)-4H-pyran; periflanthene; 2,5-dicyano-1,4-bis(10-methoxy-1,1,7,7-tetramethyljulolidyl-9-enyl) benzene; N,N′-dimethylquinacridone (abbreviation: DMQd); coumarin 6; coumarin 545T; Alq₃; 9,9′-bianthryl; 9,10-diphenylanthracene (abbreviation: DPA); 9,10-bis(2-naphthyl) anthracene (abbreviation: DNA); 2,5,8,11-tetra-t-butylperylene (abbreviation: TBP); and the like can be given. In addition to the above mentioned substances, which emit fluorescence, the following substances, which emit phosphorescence, can be used as a dopant material: bis[2-(3,5-bis(trifluoromethyl)phenyl)pyridinato-N,C²′]iridium(III)picolinato (abbreviation: Ir(CF₃ppy)₂(pic)); bis[2-(4,6-difluorophenyl)pyridinato-N,C²′]iridium(III) acetylacetonato (abbreviation: FIr(acac)); bis[2-(4,6-difluorophenyl)pyridinato-N,C²′]iridium(III) picolinato (abbreviation: Flr(pic)); tris(2-phenylpyridinato-N,C²′) iridium (abbreviation: Ir(ppy)₃); and the like.

Further, a material used for dispersing a light emitting substance is not particularly limited, and a material having an electron transporting property such as a metal complex and Alq₃ can be used in addition to a carbazole derivative such as CBP.

For example, as materials having the above describe energy relations, ITO as the anode 2, αNPD as the first hole transporting layer 3, Alq₃ as the light emitting layers 4, MTDATA as the second hole transporting layers 5, and the like can be given. Of course, the present invention is not limited to this combination.

The electron transporting layer 6 can be formed using Alq₃, bis(2-methyl-8-quinolinolato)-4-phenylphenolato-aluminum (abbreviation: BAlq₃), bathocuproin (abbreviation: BCP), tris(4-methyl-8-quinolinolato) aluminum (abbreviation: Almq₃), or the like. A materiel having a HOMO level of −5.5 to −6.0 eV is preferable.

The cathode 7 can be formed using metal, an alloy, an electrical conductive compound, a mixture thereof, and the like, which have low work function (−3.8 eV or less). As specific examples of such a cathode material, an element belonging to Group 1 or Group 2 of the periodic table, i.e., alkali metal such as lithium (Li) and cesium (Cs), alkali earth metal such as magnesium (Mg), calcium (Ca), and strontium (Sr), and an alloy containing these elements (e.g., Mg:Ag, Al:Li and the like) can be given. Furthermore, by providing a layer having an excellent electron injecting property between the cathode 7 and one of the light emitting layers 4, various conductive materials as well as the materials given as the materials given for the anode 2 such as Al, Ag, ITO, and ITO containing silicon can be used to form the cathode 7 regardless of work function.

Further, when an electron injecting layer is provided between the cathode 7 and the electron transporting layer 6, a compound of alkali metal or alkali earth metal such as lithium fluoride (LiF), cesium fluoride (CsF), and calcium fluoride (CaF₂) can be used. In addition, a layer made from a substance having an electron transporting property, which contains alkali metal or alkali earth metal, for example, Alq₃ containing magnesium (Mg) and the like can be used.

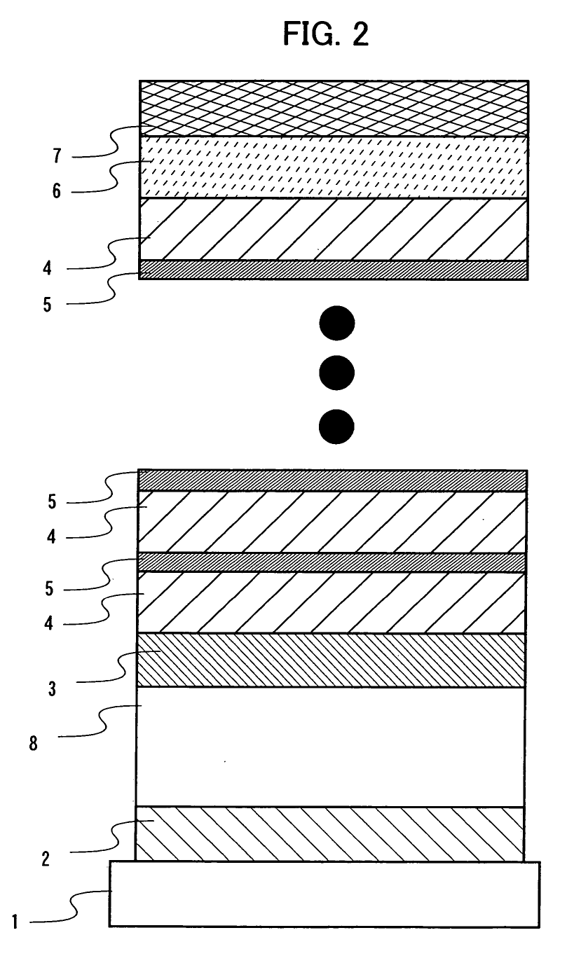

As shown in FIG. 2, a buffer layer 8 may be provided between the anode 2 and the first hole transporting layer 3. The buffer layer 8 can be formed using a mixture of an organic compound and a metal compound.

With respect to a combination of an organic compound and a metal compound, as an organic compound, an aromatic amine (i.e., having benzene ring-nitrogen bonds) based compound such as 4,4′-bis[N-(1-naphthyl)-N-phenyl-amino]-biphenyl (abbreviation: NPB or αNPD), 4,4′-bis[N-(3-methylphenyl)-N-phenyl-amino]-biphenyl (abbreviation: TPD), 4,4′,4″-tris(N,N-diphenyl-amino)-triphenylamine (abbreviation: TDATA), 4,4′,4″-tris[N-(3-methylphenyl)-N-phenyl-amino]-triphenylamine (abbreviation: MTDATA), 4,4′-bis(N-(4-(N,N-di-m-tolylamino)phenyl]-N-phenylamino}biphenyl (abbreviation: DNTPD), N,N′-bis(spiro-9,9′-bifluorene-2-yl)-N,N′-diphenylbenzidine (abbreviation: BSPB), 4,4′,4″-tris[3-methylphenyl(phenyl)amino]triphenylamine (abbreviation: m-MTDATA), 1,3,5-tris[N,N-bis(3-methylphenyl)-amino]-benzene (abbreviation: m-MTDAB), and N,N′-di(p-tolyl-N,N′-diphenyl-p-phenylenediamine (abbreviation: DTDPPA); or a phthalocyanine compound such as phthalocyanine (abbreviation: H₂Pc), copper phthalocyanine (abbreviation: CuPc), and vanadyl phthalocyanine (abbreviation: VOPc) can be used. As the metal compound, transition metal oxide is preferable. Specifically, titanium oxide, zirconium oxide, hafnium oxide, vanadium oxide, niobium oxide, tantalum oxide, chromium oxide, molybdenum oxide, tungsten oxide, manganese oxide, rhenium oxide, and the like can be given. In particular, since vanadium oxide, molybdenum oxide, tungsten oxide, and rhenium oxide have strong electron accepting properties, they are preferable. Among them, molybdenum oxide is stable in atmospheric air and easily handled, and therefore, molybdenum oxide is more preferable. Further, a metal compound is desirably contained by 5 to 80 wt %, and more preferably, by 10 to 50 wt % in an organic compound. The thickness of the buffer layer may be set to be 60 nm or more. In the present invention, driving voltage is not increased even when the thickness of the buffer layer is increased.

The first hole transporting layer 3, the light emitting layers 4, the second hole transporting layers 5, and the electron transporting layer 6 can be formed by evaporation. The buffer layer 8 can be formed by co-evaporation of an organic compound and a metal compound. The anode 2 and the cathode 7 can be formed by a known method such as sputtering and evaporation. In a case of providing a hole injecting layer and an electron injecting layer, they can be formed by a known method such as evaporation. Further, the light emitting layers 4 and the second hole transporting layers 5 can be formed by the after mentioned methods.

Here, a method for measuring a HOMO level and a LUMO level will be described. A HOMO level can be obtained by forming a thin film of a target matter over a glass substrate or the like, and then by measuring the thin film with photoelectron spectroscopy (RIKEN KEIKI CO., LTD., # AC-2) under atmospheric air.

Next, a measurement of a LUMO level will be described. First, an absorption spectrum of a target matter is measured and by using the data, an absorption end is obtained from a Tauc plot. Next, the absorption end is estimated as an optical energy gap, and an energy gap between a HOMO level and a LUMO level is calculated. Thereafter, a LUMO level is calculated by using the HOMO level obtained by the photoelectron spectroscopy under atmospheric air and the energy gap.

For example, in a case where a HOMO level of a thin film obtained by the photoelectron spectroscopy under atmospheric air is −5.28 eV and an energy gap estimated from an absorption spectrum of the thin film is 2.98 eV, a LUMO level of the thin film is −2.30 eV. Of course, this measurement method can be applied to not only this embodiment mode, but also to other embodiment modes of the present invention.

### Embodiment Mode 2

An example of the present invention will be described with reference to FIGS. 1, 2, 5, 6, and the like. A case where the carrier transporting layers are electron transporting layers will be described here.

In a light emitting device shown in FIG. 1, an anode 2; a hole transporting layer 3; light emitting layers 4 and second electron transporting layers 5, which are repeatedly stacked; a first electron transporting layer 6; and a cathode 7 are formed over a substrate 1. A hole injecting layer may be provided between the anode 2 and the hole transporting layer 3. Further, an electron injecting layer may be provided between the cathode 7 and the first electron transporting layer 6. The first and second electron transporting layers may be formed by using the same material, or different materials. Many of the second electron transporting layers 5 and the light emitting layers 4 are stacked. A thickness of each of the second electron transporting layers 5 is thinner than a thickness of each of the light emitting layers 4. The thickness of each of the second electron transporting layers 5 is preferably set to be 1 to 5 nm. The thickness of each of the light emitting layers 4 is preferably set to be 5 to 20 nm. The light emitting layers 4 have a hole transporting property. Further, 2 to n (n is a positive integer) pieces of the second electron transporting layers 5 and the light emitting layers 4 can be alternately stacked.

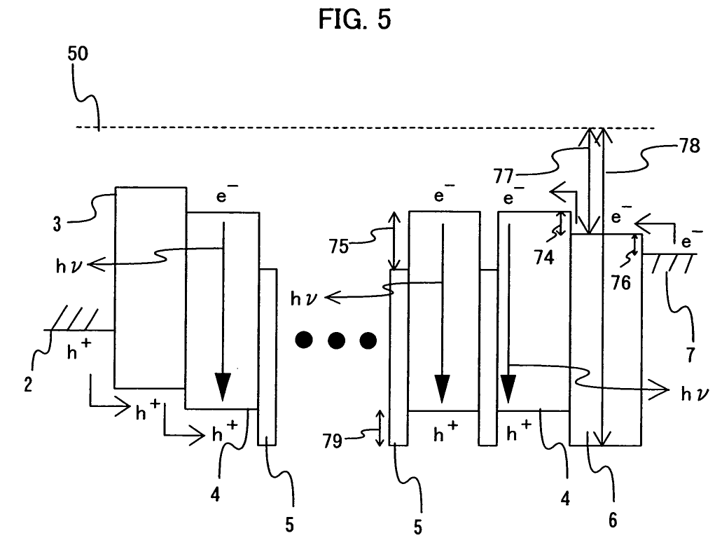

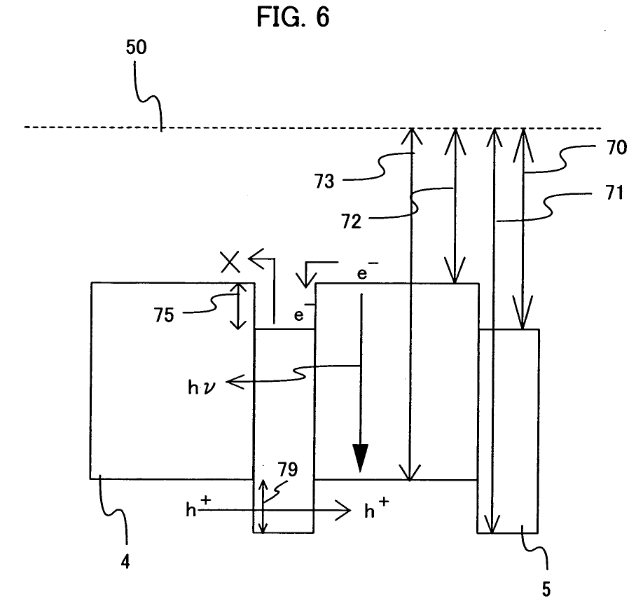

Carrier movement, and the like of the present invention will be described here with reference to FIGS. 5 and 6. FIGS. 5 and 6 show band diagrams of FIG. 1. FIG. 6 shows a band diagram of the light emitting layers 4 and the second hole transporting layers 5, which are alternately stacked. Reference numerals of FIG. 1 are also used in FIGS. 5 and 6. Reference numeral 50 indicates a vacuum level. Reference numeral 77 indicates an absolute value of an energy difference between a LUMO level of the first electron transporting layer 6 and the vacuum level 50. Reference numeral 78 indicates an absolute value of an energy difference between a HOMO level of the first electron transporting layer 6 and the vacuum level 50. Reference numeral 70 indicates an absolute value of an energy difference between a LUMO level of each of the second electron transporting layers 5 and the vacuum level 50. Reference numeral 71 indicates an absolute value of an energy difference between a HOMO level of each of the second electron transporting layers 5 and the vacuum level 50. Reference numeral 72 indicates an absolute value of an energy difference between a LUMO level of each of the light emitting layers 4 and the vacuum level 50. Reference numeral 73 indicates an absolute value of an energy difference between a HOMO level of each of the light emitting layers 4 and the vacuum level 50.

In the present invention, the absolute value 72 of the energy difference between the LUMO level of each of the light emitting layers 4 and the vacuum level is smaller than the absolute value 70 of the energy difference between the LUMO level of each of the second electron transporting layers 5 and the vacuum level (i.e., the LUMO level of each of the light emitting layers 4 is lower than the LUMO level of each of the second electron transporting layers 5). Further, the absolute value 73 of the energy difference between the HOMO level of each of the light emitting layers 4 and the vacuum level is smaller than the absolute value 71 of the energy difference between the HOMO level of each of the second electron transporting layers 5 and the vacuum level (i.e., the HOMO level of each of the light emitting layers 4 is higher than the HOMO level of each of the second electron transporting layers 5).

When positive potential is applied to the anode 2 while negative potential is applied to the cathode 7, holes (h⁺) are injected in the hole transporting layer 3 from the anode 2 and electrons (e⁺) are injected in the first electron transporting layer 6 from the cathode 7. The electrons are transported to the light emitting layers 4 from the first hole transporting layer 6, and the electrons are recombined with holes transported from the anode in the light emitting layers 4. Thus, light is emitted. Since the light emitting layers 4 have a hole transporting property, there is a high probability of recombining the electrons and holes. Note that, portions where light is emitted are indicated by hv in the drawings.

Electrons, which are not recombined with holes in one of the light emitting layers 4, are moved toward the anode 2 by a potential difference. Subsequently, the electrons are injected to the second electron transporting layer 5 next to the light emitting layer and moved inside of the second electron transporting layer 5. Because of a barrier between the second electron transporting layer 5 and the next light emitting layer 4 (i.e., an energy difference 75, which is an energy difference between the LUMO level of each light emitting layer 4 and the LUMO level of each second electron transporting layer 5), a probability of injection of the electrons to the light emitting layer 4 is reduced, and therefore, the electrons are confined in the second electron transporting layer 5. If electrons are injected in the light emitting layer 4 beyond the barrier due to accumulation of electrons and the like, the electrons are recombined with holes inside of the light emitting layer 4 so that light is emitted. Further, if electrons are not recombined with holes inside of one of the light emitting layers 4 and are injected in the second electron transporting layer 5 next to the light emitting layer 4, there is a high probability of being confined in the second electron transporting layer 5 due to the barrier between the second electron transporting layer 5 and the next light emitting layer 4 as described above. Therefore, electrons can be prevented from passing through the hole transporting layer 3 so that light emitting efficiency can be improved. In a case where the hole transporting layer 3 has a light emitting property, when electrons are injected in the hole transporting layer 3, the electrons are recombined with holes in the hole transporting layer 3 and light is emitted. When an emission wavelength of the hole transporting layer 3 is different from an emission wavelength of each of the light emitting layers 4, differences in colors are caused.

On the other hand, holes, which are not recombined with electrons in one of the light emitting layers 4, are moved toward the cathode 7 by a potential difference. In this case, since each of the second electron transporting layers 5 has a thin thickness as 1 to 5 nm, the holes pass through each of the second hole transporting layers 5 in spite of the existence of a barrier (i.e., an energy difference 79, which is an energy difference between the HOMO level of each of the light emitting layers 4 and the HOMO level of each of the second electron transporting layers 5), and then the holes are injected in the next light emitting layer 4. Thus, the holes are recombined with electrons in the light emitting layer 4 so that light is emitted. Further, even if the holes are not recombined with electrons in the light emitting layer 4, the holes are injected to the next light emitting layer 4 through the second hole transporting layer 5.

When the first electron transporting layer 6 and the second electron transporting layers 5 are formed using different materials, in order to increase an effect of confining holes, an absolute value of the energy difference 74 between the LUMO level of the first electron transporting layer 6 and the LUMO level of each of the light emitting layers 4 is preferably set to be smaller than an absolute value of the energy difference 75. This can improve a probability that electrons injected from the cathode 7 cannot move beyond the energy difference 75.

When the energy difference 76 between work function of the cathode 7 and the LUMO level of the first electron transporting layer 6 or potential applied to the anode 2 and the cathode 7 is controlled, the probability that holes cannot move beyond the energy difference 75, can be improved. When the energy difference 76 is made smaller than the energy difference 75 and voltage, by which electrons move beyond only the energy difference 76, is applied, the electrons can move beyond the energy difference 76; however, the probability of moving beyond the energy difference 75 is reduced. Accordingly, it is preferable to use the anode 2, the first electron transporting layer 6, the light emitting layers 4, the second electron transporting layers 5, and the cathode 7 having the above described relations while controlling voltage applied to the anode and the cathode.

Materials and the like, which can be used for each layer, will be described below. Note that the substrate 1 and the anode 2 can be formed using the same materials described in Embodiment Mode 1.

The cathode 7 can be formed using a substance having work function of 2.8 to 3.0 eV such as Ca, MgAg, Al, and Mg. The first electron transporting layer 6 can be formed using Alq₃, BAlq₃, BCP, CBP, and the like. In view of the energy difference between the first electron transporting layer 6 and each of the second electron transporting layers 5, a substance having a LUMO level of −2.7 to −2.4 eV is preferable. The second electron transporting layers 5 may be formed using the same material as the first electron transporting layer 6. However, in order to improve an effect of confining electrons, an energy difference between the LUMO level of the first electron transporting layer 6 and the LUMO level of each of the light emitting layers 4 may be made smaller than an energy difference between the LUMO level of each of the second electron transporting layers 5 and the LUMO level of each of the light emitting layers 4. A material having a LUMO level of −2.7 eV or less is preferably used. For example, Alq₃, BAlq₃, diphenylquinoxaline, and the like can be used.

With respect to the light emitting layers 4, an absolute value of an energy difference between the HOMO level of each of the light emitting layers 4 and the vacuum level is necessary to be made smaller than an absolute value of an energy difference between the HOMO level of each of the second electron transporting layers 5 and the vacuum level. Further, an absolute value of an energy difference between the LUMO level of each of the light emitting layers 4 and the vacuum level is necessary to be made smaller than an absolute value of an energy difference between the LUMO level of each of the second electron transporting layers 5 and the vacuum level. This makes it possible to confine electrons in the light emitting layers 4 as described above and improve light emitting efficiency. In addition, electrons can be prevented from passing through the hole transporting layer 3.

On the other hand, the thickness of each of the second electron transporting layers 5 is thinner than that of each of the light emitting layers 4 and the thickness of each of the second electron transporting layers 5 is 1 to 5 nm whereas the thickness of each of the light emitting layers 4 is 5 to 20 nm, and therefore, holes are injected in the light emitting layers 4 through the second hole transporting layers 5 even though there are above described energy relations.

The light emitting layers 4 can be formed using NPB, TCTA, TPD, or the like. A material having a LUMO level of −2.5 eV or more is preferable.

As described in Embodiment Mode 1, each of the light emitting layers 4 may be a host-guest type layer in which a light emitting substance (a dopant material), which becomes a light emission center, is dispersed in a layer made from a material (a host material) having a larger energy gap than that of the light emitting substance.

The hole transporting layer 3 can be formed using, for example, an aromatic amine (i.e., having benzene ring-nitrogen bonds) compound such as TDATA, MTDATA, DNTPD, and αNPD.

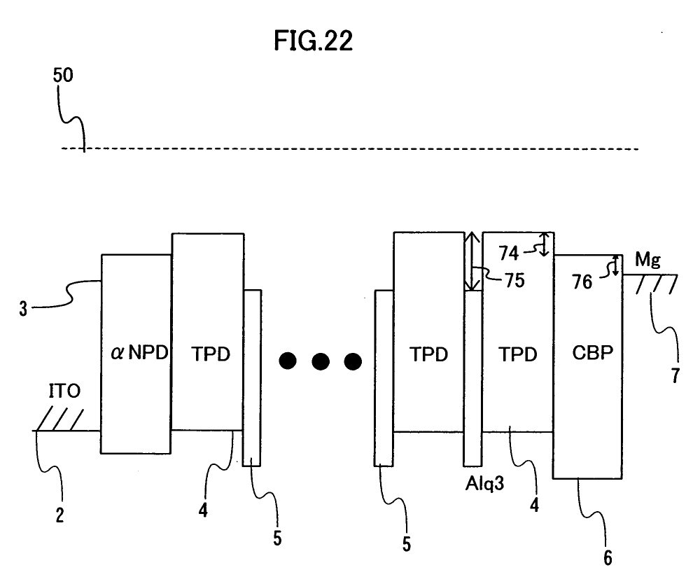

For example, as materials having the above describe energy relations, a combination of Mg as the cathode 7, CBP as the first electron transporting layer 6, TPD as the light emitting layers 4, Alq₃ as the second electron transporting layers 5, and the like can be given. Of course, the present invention is not limited to this combination. Furthermore, a band diagram in a case where αNPD is used as the hole transporting layer 3 and ITO is used as the anode, is shown in FIG. 22.

In FIG. 22, an absolute value of an energy difference between a LUMO level of each of the light emitting layers 4 and the vacuum level is smaller than an absolute value of an energy difference between a LUMO level of each of the second electron transporting layers and the vacuum level. An absolute value of an energy difference between a HOMO level of each of the light emitting layers and the vacuum level is smaller than an absolute value of an energy difference between a HOMO level of each of the second electron transporting layers and the vacuum level.

Further, the energy difference 74 between the LUMO level of the first electron transporting layer and the LUMO level of each of the light emitting layers is smaller than the energy difference 75 between the LUMO level of each of the second electron transporting layers and the LUMO level of each of the light emitting layers.

The energy difference 76 between the work function of the cathode and the LUMO level of the first electron transporting layer is smaller than the energy difference between the LUMO level of each of the second electron transporting layers and the LUMO level of each of the light emitting layers. Therefore, electrons can be confined and light emitting efficiency can be improved.

As shown in FIG. 2, a buffer layer 8 may be provided between the anode 2 and the first hole transporting layer. The buffer layer 8 can be formed using a mixture of an organic compound and a metal compound. The thickness of the buffer layer 8 may be set to be 60 nm or more. In the present invention, driving voltage is not increased even when the thickness of the buffer layer is increased.

The first electron transporting layer 6, the light emitting layers 4, the second electron transporting layers 5, and the hole transporting layer 6 can be formed by evaporation. The buffer layer 8 can be formed by co-evaporation of an organic compound and a metal compound. The anode 2 and the cathode 7 can be formed by a known method such as sputtering and evaporation. In a case of providing a hole injecting layer and an electron injecting layer, they can be formed by a known method such as evaporation. Further, the light emitting layers 4 and the second electron transporting layers 5 can be formed by the after mentioned method.

The method for measuring a HOMO level and a LUMO level is the same as Embodiment Mode 1.

### Embodiment Mode 3

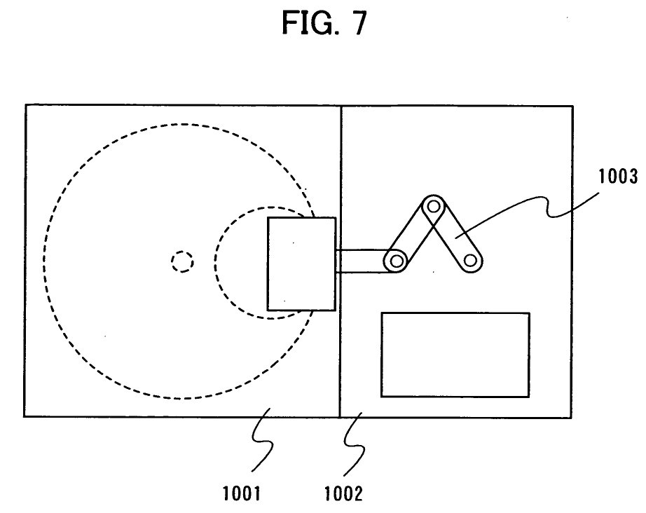

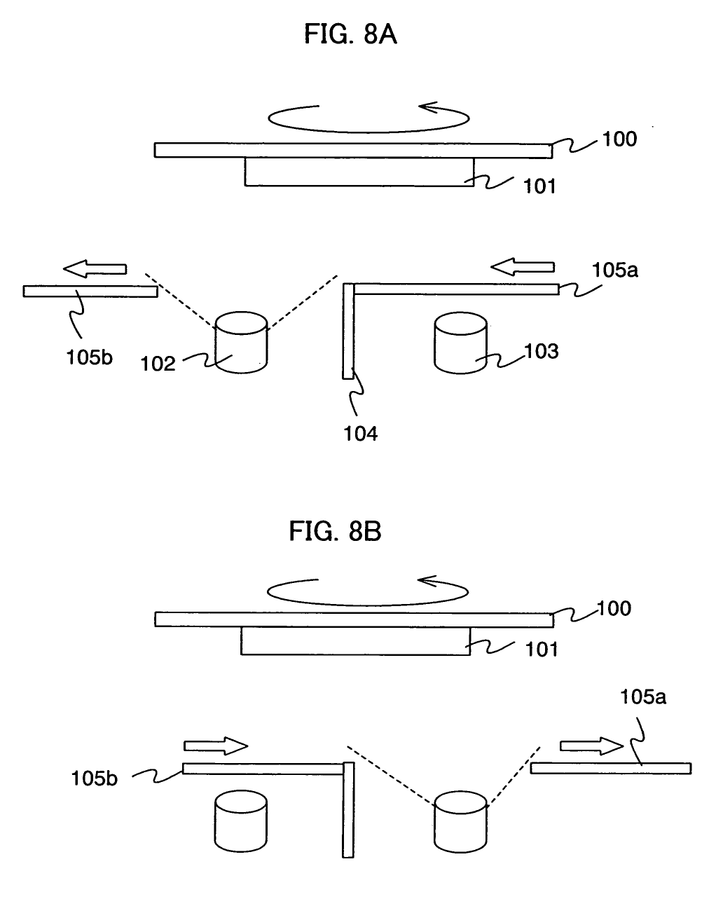

An evaporation device used in this embodiment mode and a method for manufacturing a multistacked structure described in Embodiment Modes 1 and 2 by using the evaporation device, will be described with reference to FIG. 7, FIGS. 8A and 8B, FIG. 9, FIG. 10, FIGS. 11A and 11B, FIGS. 12A and 12B, and FIGS. 13A and 13B.

In the evaporation device used in this embodiment mode, a treatment chamber 1001 in which a target matter is subjected to evaporation treatment, and a transferring chamber 1002 are provided. The target matter is transferred to the treatment chamber 1001 through the transferring chamber 1002. The transferring chamber 1002 is provided with an arm 1003 for moving the target matter (FIG. 7).

As shown in FIGS. 8A and 8B, in the treatment chamber 1001, a fixing portion 100 for fixing a substrate 101, which is a target matter, an evaporation source 102 filled with a light emitting material, and an evaporation source 103 filled with a carrier transporting material are provided. The evaporation source 102 and the evaporation source 103 are divided by a partition 104. Further, a shutter 105b is provided over the evaporation source 102 filled with the light emitting material whereas a shutter 105a is provided over the evaporation source 103 filled with the carrier transporting material.

When a dopant material is added to the light emitting material, an evaporation source for the dopant material is provided along with the evaporation source 102 for a host material, and the host material and the dopant material are co-evaporated.

As shown in FIG. 8A, when the shutter 105b is opened while the shutter 105a is closed, the light emitting material is evaporated over the substrate 101 whereas the carrier transporting material is not evaporated thereover. Next, as shown in FIG. 8B, when the shutter 105b is closed while the shutter 105a is opened, the carrier transporting material is evaporated over the substrate 101 whereas the light emitting material is not evaporated thereover. According to this method, the carrier transporting material and the light emitting material can be alternately evaporated, and hence, a multistacked structure can be formed.

In order to make a thickness of each of second carrier transporting layers 5 thinner than that of each of light emitting layers 4 in the present invention, opening time of the shutter 105b may be made longer than opening time of the shutter 105a. This can reduce the evaporation amount of the carrier transporting material so that the thickness of the carrier transporting layers can be reduced. By controlling opening time of the shutters 105a and 105b in such a manner, the structures described in the above embodiment modes can be formed.

At this moment, a film thickness can be controlled by changing an evaporation rate. When the evaporation rate is reduced, the evaporation amount per unit time is reduced. On the other hand, when an evaporation rate is increased, an evaporation amount is increased, making it possible to increase a film thickness. In a case where an evaporation rate of the carrier transporting material is reduced when the shutter 105a is opened and an evaporation rate of the light emitting material is increased when the shutter 105b is opened, the thickness of each of the carrier transporting layers can be made thinner than the thickness of each of the light emitting layers.

Further, an absorption rate may be changed by changing a temperature of the substrate.

The substrate 101 may be rotated like arrows. By rotating the substrate 101, a carrier transporting layer having an even thickness and a light emitting layer having an even thickness can be formed over the substrate.

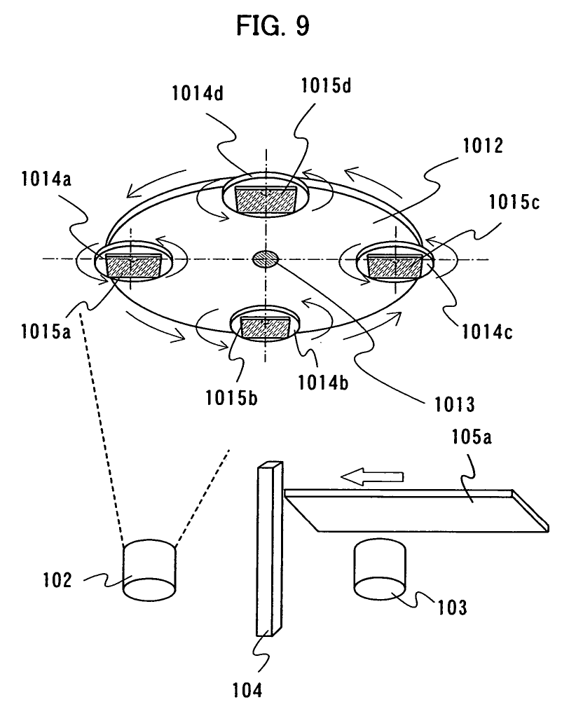

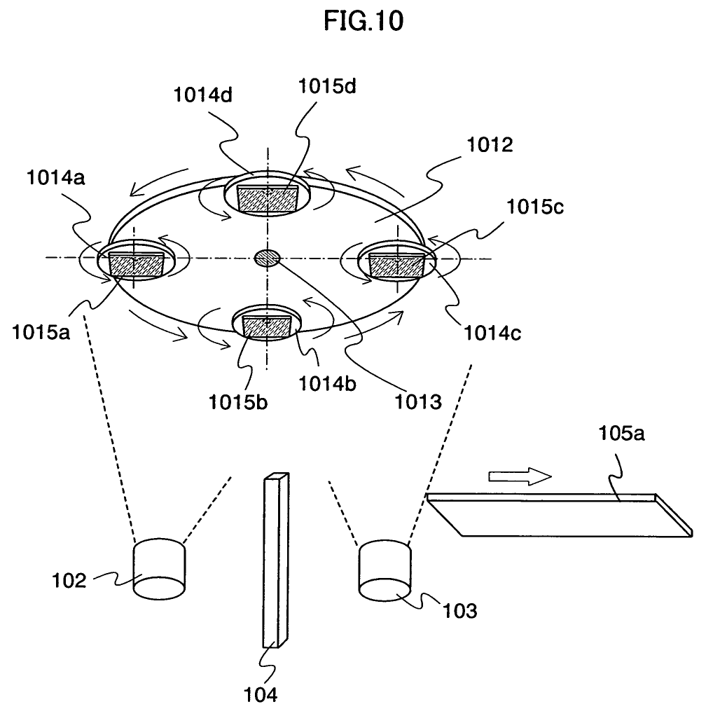

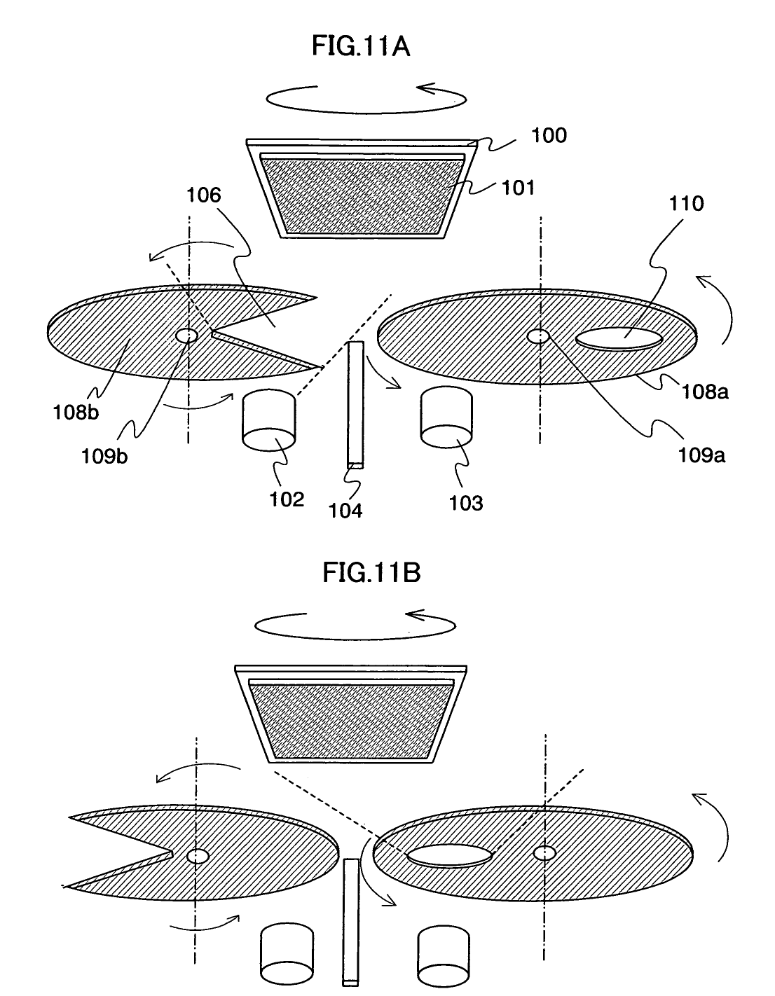

The component parts provided inside of the treatment chamber 1001 is not limited to the things shown in FIGS. 8A and 8B, and for example, the structures as shown in FIG. 9, FIG. 10, FIGS. 11A and 11B, FIGS. 12A and 12B, and FIGS. 13A and 13B may be employed.

In each of FIG. 9 and FIG. 10, a fixing portion for fixing a substrate, which is a target matter, an evaporation source 102 filled with a light emitting material, and an evaporation source 103 filled with a carrier transporting material are provided in an evaporation device. Further, the evaporation source 102 and the evaporation source 103 are divided by the partition 104. In addition, a shutter 105a is provided over the evaporation source 103 filled with the carrier transporting material.

As shown in FIG. 9, when the shutter 105a is closed, the light emitting material is evaporated over a substrate 1015 whereas the carrier transporting material is not evaporated thereover. On the other hand, when the shutter 105a is opened as shown in FIG. 10, the carrier transporting material is evaporated over a substrate 1015.

When opening time of the shutter 105a is shortened, an evaporation amount of the carrier transporting material is reduced. When opening time of the shutter 105a is lengthened, the evaporation amount of the carrier transporting material can be increased. Controlling the evaporation amounts of the carrier transporting material and light emitting material by opening and closing the shutter 105a makes it possible to control the thickness of each carrier transporting layer and the thickness of each light emitting layer. The steps described so far are the same as FIGS. 8A and 8B.

The fixing portion for fixing a substrate includes a first rotating plate 1012, which rotates around an axis 1013, and a plurality of second rotating plates 1014a to 1014d provided over the first rotating plate 1012. The second rotating plates 1014a to 1014d are independently rotated around axes, which are provided for each of the second rotating plates separately from the axis 1013. Substrates 1015a to 1015d are provided over the second rotating plates 1014a to 1014d.

The substrate 1015a is fixed over the second rotating plate 1014a, the substrate 1015b is fixed over the second rotating plate 1014b, the substrate 1015c is fixed over the second rotating plate 1014c, and the substrate 1015d is fixed over the second rotating plate 1014d.

Further, the first rotating plate 1012 and the second rotating plates 1014a to 1014d, over which the substrates are fixed, are rotated. By the rotations of the second rotating plates, the substrates also rotate by themselves, that is, rotate on their axes. This is the same as the rotation of the substrate shown in each of FIGS. 8A and 8B. By rotating the substrates by themselves, a light emitting layer having an even thickness and a carrier transporting layer having an even thickness can be formed.

On the other hand, the substrates are also rotated around the axis 1013 by the rotation of the first rotating plate 1012. As shown in FIG. 10 in which the shutter 105a is opened, when a distance between the substrate 1015a and the evaporation source 102 of the light emitting material is shorter than a distance between the substrate 1015a and the evaporation source 103 of the carrier transporting material, a larger amount of the light emitting material is evaporated over the substrate 1015a than the carrier transporting material so that a light emitting layer is formed thereover. On the other hand, when a distance between the substrate 1015c and the evaporation source 103 of the carrier transporting material is shorter than a distance between the substrate 1015c and the evaporation source 102 of the light emitting material, a larger amount of the carrier transporting material is evaporated over the substrate 1015c than the light emitting material so that a carrier transporting layer is formed thereover.

Next, in a case where the position of the second rotating plate 1014a inside of the treatment chamber 1001 is changed by the rotation of the first rotating plate 1012, the substrate 1015a is placed at the position of the second rotating plate 1014c of FIG. 9, and a distance between the substrate 1015a and the evaporation source 103 of the carrier transporting material becomes shorter than a distance between the substrate 1015a and the evaporation source 102 of the light emitting material. In this case, a larger amount of the carrier transporting material is evaporated over the substrate 1015a than the light emitting material so that a carrier transporting layer is formed thereover. Accordingly, light emitting layers and carrier transporting layers can be alternately stacked, and hence, a multistacked structure can be formed.

Since the thickness of each carrier transporting layer is thinner than the thickness of each light emitting layer in the present invention, the thickness of the carrier transporting layer may be controlled by using the shutter 105a, or an evaporation amount may be controlled by differing an evaporation rate of the light emitting material from an evaporation rate of the carrier transporting material. Further, by changing a temperature of the substrate, an absorption rate may be changed so as to change film thicknesses.

As mentioned above, by changing the positions of the substrates 1015a to 1015d with respect to the evaporation sources 102 and 103, light emitting layers and carrier transporting layers can be alternately stacked so that a multistacked structure can also be realized.

Note that, the shapes of the first rotating plate 1012 and the second rotating plates 1014a to 1014d are not particularly limited, and each of the first and second rotating plates may have a polygonal shape such as a square shape, in addition to a circular shape as shown in FIG. 9, FIG. 10, and FIGS. 11A and 11B. Further, the second rotating plates 1014a to 1014d may not necessarily be provided; however, by providing the second rotating plates 1014a to 1014d, unevenness in thickness of a film provided over a target matter and the like can be reduced.

In the case of the structure as shown in each of FIGS. 9 and 10, the structure has a batch type and has an advantage of processing a plurality of substrates at one time.

In each of FIGS. 11A and 11B, masks 108a and 108b, which rotate around axes 109a and 109b, are provided over an evaporation source of a carrier transporting material and an evaporation source of a light emitting material. Holes 106 and 110 are provided in the masks 108a and 108b.

When the hole 106 provided in the mask 108b is positioned over the evaporation source 102 of the light emitting material, the light emitting material is evaporated over a substrate 101. At this moment, when the hole 110 provided in the mask 108a is not positioned over the evaporation source 103 of the carrier transporting material, the carrier transporting material is not evaporated over the substrate (FIG. 11A).

Next, when the mask 108 is rotated and the hole 106 provided in the mask 108b is not positioned over the evaporation source 102 of the light emitting material, the light emitting material is not evaporated over the substrate. At this time, when the hole 110 provided in the mask 108a is positioned over the evaporation source 103 of the carrier transporting material, the carrier transporting material is evaporated over the substrate (FIG. 11B). Accordingly, by using these masks and controlling rotation speed of the masks, light emitting layers and carrier transporting layers can be alternately stacked so that a multistacked structure can be formed.

Further, an evaporation amount may be changed by changing evaporation speed of the carrier transporting material.

Furthermore, by changing a temperature of the substrate, an absorption rate may be changed.

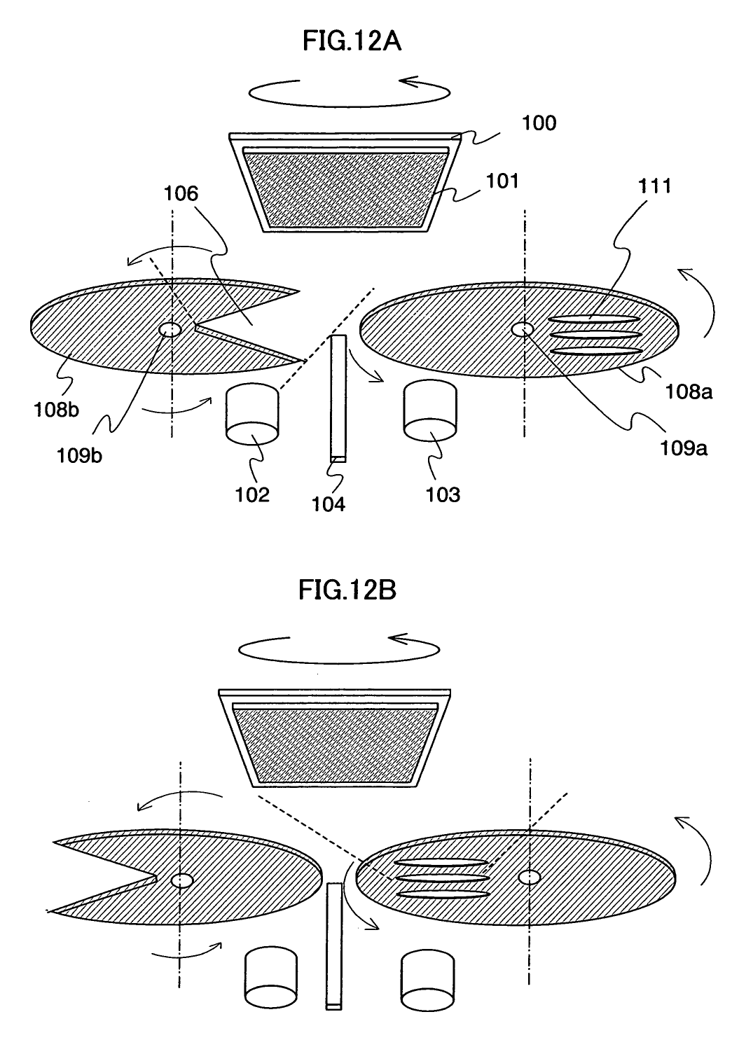

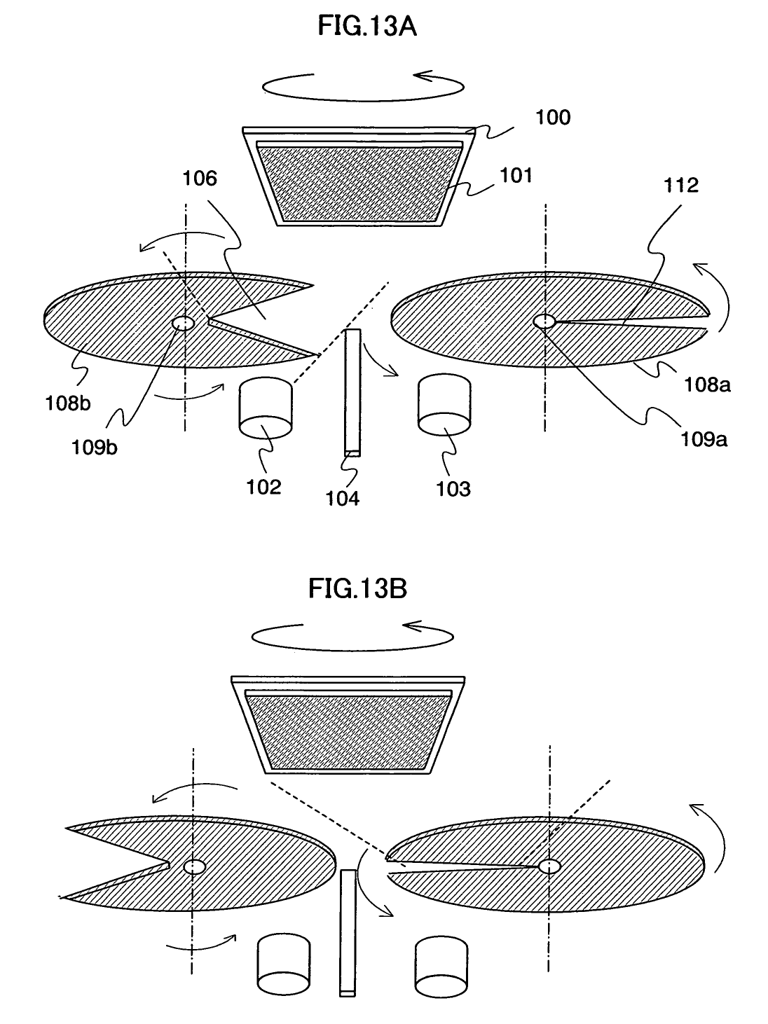

A shape of the hole in the mask may be changed according to need. A slit 111 may be provided (FIGS. 12A and 12B). The shape of the hole of the mask 108a may be changed to a shape denoted by reference numeral 112 (FIGS. 13A and 13B). In addition, the shape of the hole of the mask 108b may be changed to a circular shape denoted by reference numeral 110. Alternatively, a slit denoted by reference numeral 111 may be provided as a substitute for the hole of the mask 108b.

In the same manner as FIGS. 9A and 9B or FIGS. 10A and 10B, in each of the structures as shown in FIGS. 11A and 11B, FIGS. 12A and 12B, and FIGS. 13A and 13B, the first rotating plate 1012, which rotates around the axis 1013, may be provided and the plurality of second rotating plates 1014a to 1014d, may be provided over the first rotating plate 1012, substrates are fixed over the second rotating plates 1014a to 1014d, and light emitting layers and carrier transporting layers may be alternately stacked by rotating the first and second rotating plates so as to form a multistacked structure. Note that, this embodiment mode can be combined with any structure of the above embodiment modes.

### Embodiment Mode 4

A structural example of a light emitting device of the present invention and a method for manufacturing thereof will be described with reference to FIG. 1 and the like. A case where the carrier transporting layers are hole transporting layers, will be described here. In the drawings, reference numeral 1 indicates a substrate; 2, an anode; 3, a first hole transporting layer; 4, light emitting layers; 5, second hole transporting layers; 6, an electron transporting layer; and 7, a cathode.

The anode 2 is formed over the glass substrate using ITO by sputtering.

The first hole transporting layer 3 is formed over the anode 2 using αNPD by evaporation.

The plurality of light emitting layers 4 and the plurality of second hole transporting layers 5 are alternately stacked over the first hole transporting layer 3. The light emitting layers 4 are formed using Alq₃. The second hole transporting layers 5 are formed using MTDATA.

The light emitting layers 4 and the hole transporting layers 5 are formed by using the evaporation device shown in FIGS. 8A and 8B. The evaporation source 102 is filled with a light emitting material for the light emitting layers 4 and the evaporation source 103 is filled with a hole transporting material for the second hole transporting layers 5. The light emitting material and the hole transporting material are heated and vaporized in vacuum. An evaporation rate of each of the light emitting material and the hole transporting material is set to be 0.01 to 0.4 nm/s.

A rate between opening time of the shutter 105a and opening time of the shutter 105b is set to be 10:1 to 4:1. When the shutter 105b is opened, the shutter 105a is closed. On the other hand, when the shutter 105a is opened, the shutter 105b is closed.

Accordingly, a structure, in which 2 to 10 sets of one light emitting layer 4 and one second hole transporting layer 5 are stacked and each light emitting layer 4 has a thickness of 5 to 20 nm while each second hole transporting layer 5 has a thickness of 1 to 5 nm, is obtained. For example, in a case where two sets of one light emitting layer 4 and one second hole transporting layer 5 are provided, the substrate 1, the anode 2, the first hole transporting layer 3, the light emitting layer 4, the second hole transporting layer 5, another light emitting layer 4, another second hole transporting layer 5, still another light emitting layer 4, the electron transporting layer 6, and the cathode 7, are stacked. That is, the set of one light emitting layer 4 and one second hole transporting layer 5 are stacked two times. Note that, a last light emitting layer 4 is provided over the lamination of 2 to 10 sets of one light emitting layer 4 and one second hole transporting layer 5.

Next, the electron transporting layer 6 is formed over the last light emitting layer 4 using Almq₃ by evaporation. Thereafter, the cathode 7 is formed using MgAg by evaporation.

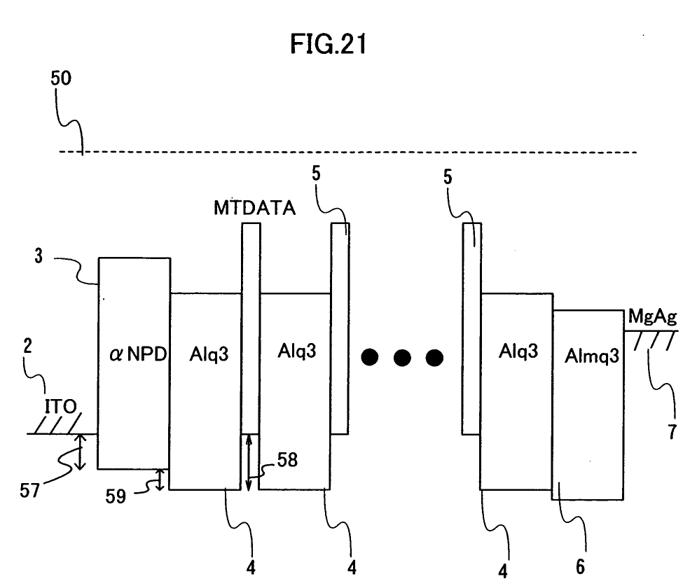

An energy band diagram of this embodiment mode will be shown in FIG. 21. In FIG. 21, an absolute value of an energy difference between a LUMO level of each of the light emitting layers 4 and a vacuum level is larger than an absolute value of an energy difference between a LUMO level of each of the second hole transporting layers and the vacuum level (i.e., the LUMO level of each of the light emitting layers 4 is lower than the LUMO level of each of the hole transporting layers). An absolute value of an energy difference between a HOMO level of each of the light emitting layers 4 and the vacuum level is larger than an absolute value of an energy difference between a HOMO level of each of the second hole transporting layers 5 and the vacuum level (i.e., the HOMO level of each of the light emitting layers is lower than the HOMO level of each of the second hole transporting layers).

Further, an energy difference 59 between a HOMO level of the first hole transporting layer and the HOMO level of each of the light emitting layers is smaller than an energy difference 58 between the HOMO level of each of the second hole transporting layers and the HOMO level of each of the light emitting layers.

Furthermore, an energy difference 57 between work function of the anode and the HOMO level of the first hole transporting layer is smaller than an energy difference 58 between the HOMO level of each of the second hole transporting layers and the HOMO level of each of the light emitting layers. Therefore, holes can be confined so that light emitting efficiency can be improved.

Note that a buffer layer may be provided between the anode 2 and the first hole transporting layer 3. In addition, a hole injecting layer and an electron injecting layer may be provided. Each of the light emitting layers 4 may be formed by using a host material doped with a dopant material. For example, a dopant material such as a material mentioned in the above embodiment modes or rubrene can be doped in Alq₃, which is a host material.

The method using the evaporation device as shown in FIGS. 8A and 8B is shown here; however, the present invention is not limited thereto. Of course, a multistacked structure can be formed by using any methods shown in FIGS. 9A and 9B, FIGS. 10A and 10B, FIGS. 11A and 11B, FIGS. 12A and 12B, and FIGS. 13A and 13B. The manufacturing method in each case is as the same as the above described embodiment modes.

As described above, by applying this structure, a multistacked structure in which light emitting layers including an organic compound and carrier transporting layers including an organic compound are alternately stacked, can be formed. Since this multistacked structure is different from a stacked structure of layers made from an organic compound and layers made from an inorganic compound, stress is not generated so that a light emitting device having less deterioration in characteristics can be obtained. In addition, a light emitting device having high light emitting efficiency can be obtained.

In the present invention, the light emitting layers and the carrier transporting layers have different polarities form each other, and a thickness of each of the carrier transporting layers is thinner than that of each of the light emitting layers. In addition, the light emitting layers and the carrier transporting layers have the above described LUMO levels and HOMO levels. Accordingly, carriers having the same polarity as the carrier transporting layers can be easily confined, and carriers having different polarity from the carrier transporting layers move by a tunnel effect. That is, one of carriers can be confined, and hence, light emitting efficiency can be improved.

Further, by providing a buffer layer formed using an organic compound and a metal compound between an electrode and the carrier transporting layer, flatness can be improved. Moreover, by implementing the manufacturing method of this embodiment mode, a multistacked structure can be easily formed.

### Embodiment Mode 5

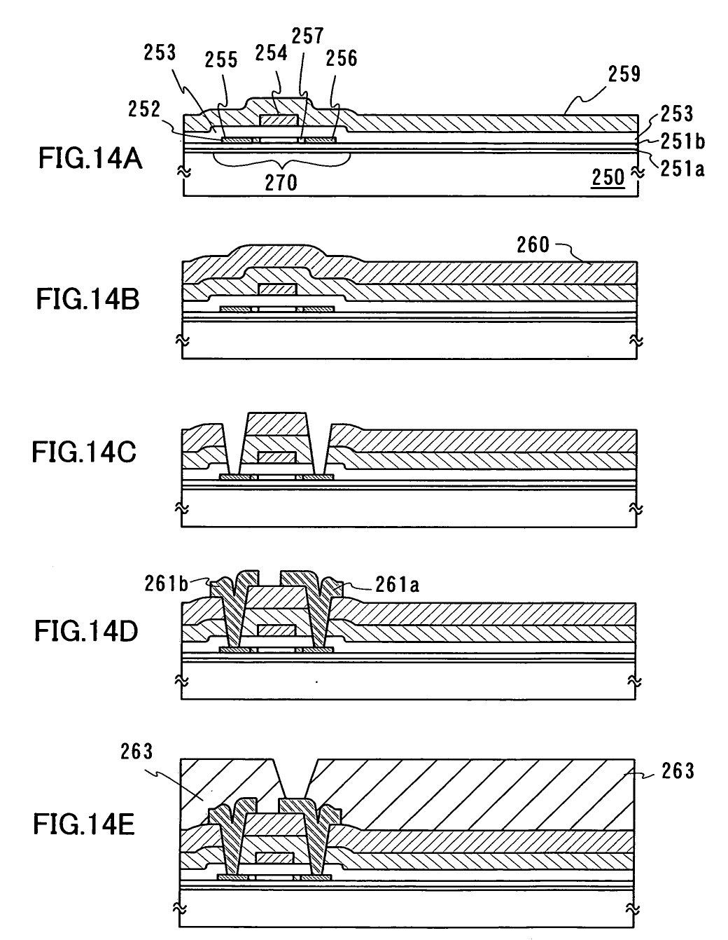

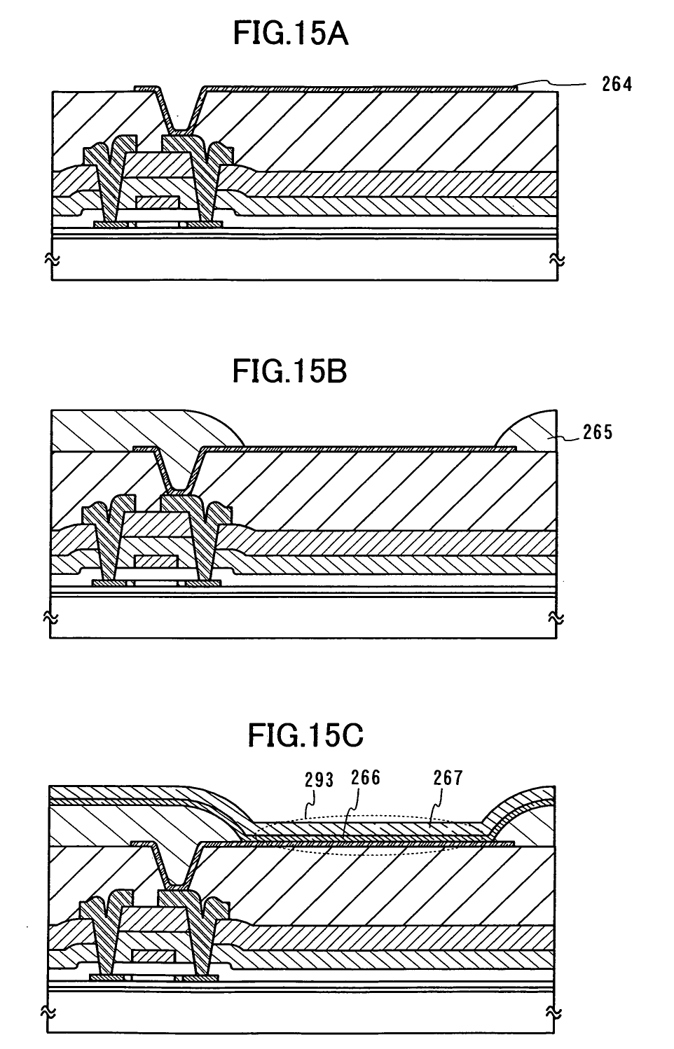

In this embodiment mode, a light emitting device of the present invention will be described while showing a method for manufacturing the light emitting device with reference to FIGS. 14A to 14D and FIGS. 15A to 15C. An example of manufacturing an active matrix light emitting device will be described in this embodiment mode. Note that the present invention is not limited to the active matrix light emitting device, and can be applied to a passive matrix light emitting device.

First, a first base insulating layer 251a and a second base insulating layer 251b are formed over a substrate 250, and then a semiconductor layer is formed over the second base insulating layer 251b (FIG. 14A).

As the substrate 250, glass, quartz, plastic (such as polyimide, acrylic, polyethyleneterephthalate, polycarbonate, polyacrylate, and polyethersulfone), and the like can be used. A substrate made from such a material can be polished by CMP or the like, if required. In this embodiment mode, a glass substrate is used.

The first base insulating layer 251a and the second base insulating layer 251b are provided to prevent an element such as alkali metal and alkali earth metal, which adversely affects a characteristic of the semiconductor layer from dispersing in the semiconductor layer. As materials of the first and second base insulating layers, silicon oxide, silicon nitride, silicon oxide containing nitrogen, silicon nitride containing oxygen, and the like can be used. In this embodiment mode, the first base insulating layer 251a is formed using silicon nitride and the second base insulating layer 251b is formed using silicon oxide. A base insulating film including two layers of the first base insulating layer 251a and the second base insulating layer 251b is provided in this embodiment mode. Alternatively, a base insulating film including a single layer or two or more layers may be provided. Further, if dispersion of an impurity penetrating from the substrate causes no problems, the base insulating layers are not necessary to be provided.

In this embodiment mode, the semiconductor layer formed after the first and second base insulating layers are obtained by crystallizing an amorphous silicon film by laser beam. The amorphous silicon film is formed over the second base insulating layer 251b to have a thickness of 25 to 100 nm (preferably, 30 to 60 nm). As a method for forming the amorphous silicon film, a known method such as sputtering, reduced pressure CVD, and plasma CVD, can be used. Thereafter, heat treatment is performed at 400 to 500° C. (for example, 500° C. for one hour) to perform dehydrogenation.

Subsequently, the amorphous silicon film is crystallized by using a laser irradiation apparatus to form a crystalline silicon film. In this embodiment mode, an excimer laser is used in laser crystallization. Laser beam oscillated from the laser irradiation apparatus is processed into a linear beam spot by using an optical system. The amorphous silicon film is crystallized by being irradiated with the linear beam spot. The thus obtained crystalline silicon film is used as the semiconductor layer.

As other method for crystallizing an amorphous silicon film, there are a method by which crystallization is performed only by heat treatment, and a method by which crystallization is performed by heat treatment with use of a catalytic element promoting crystallization. As an element promoting crystallization, nickel, iron, palladium, tin, lead, cobalt, platinum, copper, gold, and the like can be given. When using such an element promoting crystallization, the crystallization can be carried out at a lower temperature and a shorter time as compared to a case of performing crystallization only by heat treatment. Therefore, the glass substrate and the like are less damaged by the crystallization. When crystallization is performed only by heat treatment, a quartz substrate, which is resistant to heat, may be used as the substrate 250. Further, crystallization may be performed by a combination of laser irradiation and heat treatment. That is, after crystallizing an amorphous silicon film by heat treatment using a catalytic element for promoting crystallization, the crystallized silicon film may be further crystallized by laser irradiation.

Subsequently, a minute amount of impurity is doped in the semiconductor layer so as to control a threshold value, or, channel doping is performed, if required. To obtain a required threshold value, an impurity (such as phosphorus and boron) imparting an N-type conductivity or a P-type conductivity is doped in the semiconductor layer by ion doping or the like.

Thereafter, as shown in FIG. 14A, the semiconductor layer is patterned in to a predetermined shape to obtain an island-like semiconductor layer 252. The patterning is performed in such a way that a photoresist is formed over the semiconductor layer, a predetermined mask shape is exposed and baked to form a resist mask over the semiconductor layer, and the semiconductor layer is etched by utilizing the resist mask.

Subsequently, a gate insulating layer 253 is formed to cover the semiconductor layer 252. The gate insulating layer 253 is formed using an insulating layer containing silicon by plasma CVD or sputtering so as to have a thickness of 40 to 150 nm. In this embodiment mode, silicon oxide is used to form the gate insulating layer 253.

Next, a gate electrode 254 is formed over the gate insulating layer 253. The gate electrode 254 may be formed by using an element selected from tantalum, tungsten, titanium, molybdenum, aluminum, copper, chromium, and niobium; or an alloy material or a compound material mainly containing these elements. Further, a semiconductor film typified by a polycrystalline silicon film doped with an impurity element such as phosphorus may be used. Furthermore, an AgPdCu alloy may be used.

In this embodiment mode, the gate electrode 254 is formed to have a single layer. Alternatively, the gate electrode 254 may have a stacked structure including two or more layers, for example, a lower layer made from tungsten and an upper layer made from molybdenum. In a case where the gate electrode is formed to have a stacked structure, the above mentioned materials may be used. Further, a combination of these materials may be arbitrarily selected. The gate electrode 254 is etched by utilizing a mask made from a photoresist.

Subsequently, a high concentration impurity is doped into the semiconductor layer 252 while utilizing the gate electrode 254 as a mask. Thus, a thin film transistor 270 including the semiconductor layer 252, the gate insulating layer 253, and the gate electrode 254, is formed. In this case, an LDD region 257 may be provided by using low-speed ion doping or high-speed ion doping in addition to a source region 255 and a drain region 256.

Note that processes of manufacturing the thin film transistor are not particularly limited, and may be arbitrarily changed so as to manufacture a transistor having a desired structure.

In this embodiment mode, a top-gate thin film transistor using the crystalline silicon film, which is crystallized by laser crystallization, is used. Alternatively, a bottom-gate thin film transistor using an amorphous semiconductor film can be used for a pixel portion. The amorphous semiconductor film can be formed by using not only silicon but also silicon germanium. When using silicon germanium, a concentration of germanium is preferably set to be about 0.01 to 4.5 atomic %.

Further, a microcrystalline semiconductor film (semiamorphous semiconductor) in which 0.5 to 20 nm crystal grains can be observed in an amorphous semiconductor, may be used. Fine crystals, in which 0.5 to 20 nm crystal grains can be observed, are also referred to as microcrystals (μc).

Semiamorphous silicon (also referred to as SAS), which is a semiamorphous semiconductor, can be obtained by glow discharge decomposition of silane-based gas. As typical silane-based gas, SiH₄ can be given, and in addition, Si₂H₆, SiH₂Cl₂, SiHCl₃, SiCl₄, SiF₄ and the like can be used. By diluting such silane-based gas with hydrogen or a mixture of hydrogen and one or more rare gas elements selected from helium, argon, krypton, and neon, the SAS can be formed easily. The dilution ratio of the silane-based gas is preferably set to be in the range of 1:10 to 1:1,000. The semiamorphous silicon may be formed by glow discharge decomposition at the pressure of about 0.1 to 133 Pa. The high-frequency power for glow discharge may be set to be 1 to 120 MHz, and preferably, 13 to 60 MHz. A substrate heating temperature may be set to be 300° C. or less, and preferably, 100 to 250° C.

Raman spectrum of the thus formed SAS is shifted toward lower wavenumbers than 520 cm⁻¹. The diffraction peaks of (111) and (220), which are believed to be derived from Si crystal lattice, are observed in the SAS by X-ray diffraction. The semiamorphous semiconductor contains hydrogen or halogen of at least 1 atomic % or more as an agent for terminating dangling bonds. With respect to impurity elements contained in the film, each concentration of impurities for atmospheric constituents such as oxygen, nitrogen, and carbon is preferably set to be 1×10²⁰ cm⁻³ or less. In particular, the oxygen concentration is set to be 5×10¹⁹ cm⁻³ or less, and preferably, 1×10¹⁹ cm⁻³ or less. The mobility μ of a TFT using the SAS is 1 to 10 cm²/Vsec.

Moreover, the SAS may be further crystallized by laser irradiation.

Subsequently, an insulating film (hydrogenated film) 259 is formed by using silicon nitride so as to cover the gate electrode 254 and the gate insulating layer 253. The insulating film (hydrogenated film) 259 is heated at 400 to 500° C. (for example, 480° C. for about 1 hour) to activate the impurity element and hydrogenate the semiconductor layer 252.

A first interlayer insulating layer 260 is formed to cover the insulating film (hydrogenated film) 259. As a material for forming the first interlayer insulating layer 260, silicon oxide, acrylic, polyimide, siloxane, a low-k material, and the like may be used. In this embodiment mode, a silicon oxide film is formed as the first interlayer insulating layer (FIG. 14B).

Next, contact holes that reach the semiconductor layer 252 are formed. The contact holes can be formed by etching to expose the semiconductor layer 252 through the contact holes. The contact holes can be formed by either wet etching or dry etching. Further, they may be formed by etching one or more times depending on a condition. When etching is performed plural times, both wet etching and dry etching may be used (FIG. 14C).

A conductive layer is formed to cover the contact holes and the first interlayer insulating layer 260. This conductive layer is processed into a desired shape to form a connection portion 261a, a wiring 261b, and the like. This wiring may have a single layer made from aluminum, copper, an aluminum-carbon-nickel alloy, an aluminum-carbon-molybdenum alloy, or the like. Further, the wiring may have a structure formed by laminating molybdenum, aluminum, and molybdenum from the side of a substrate, a structure formed by laminating titanium, aluminum, and titanium from the side of a substrate, or a structure formed by laminating titanium, titanium nitride, aluminum, and titanium from the side of a substrate (FIG. 14D).

Thereafter, a second interlayer insulating layer 263 is formed to cover the connection portion 261a, the wiring 261b, and the first interlayer insulating layer 260. As a material of the second interlayer insulating layer 263, a film having a self-planarizing property such as acrylic, polyimide, and siloxane is preferably used. In this embodiment mode, siloxane is used to form the second interlayer insulating layer 263 (FIG. 14E).

Subsequently, an insulating layer may be formed using silicon nitride or the like over the second interlayer insulating layer 263 (not shown). This insulating layer is formed to prevent the second interlayer insulating layer 263 from being etched more than necessary in etching a pixel electrode that will be formed later. Therefore, when a ratio of the etching rates between the pixel electrode and the second interlayer insulating layer 263 is large, this insulating layer may not be provided. Next, a contact hole is formed through the second interlayer insulating layer 263 to reach the connection portion 261a.

A conductive layer having a light transmitting property is formed to cover the contact hole and the second interlayer insulating layer 263 (or the insulating layer). Thereafter, the conductive layer having the light transmitting property is processed to form a first electrode 264 of a light emitting element. The first electrode 264 is electrically connected to the connection portion 261a (FIG. 15A).

The first electrode 264 serves as an anode. The first electrode 264 can be formed by using a conductive film as shown in the above described embodiment modes.

Next, an insulating layer is formed using an organic material or an inorganic material to cover the second interlayer insulating layer 263 (or the insulating layer) and the first electrode 264. Subsequently, the insulating layer is processed to expose a part of the first electrode 264 so as to form a partition wall 265. A photosensitive organic material (such as acrylic and polyimide) is preferably used as a material of the partition wall 265. In addition, the partition wall may be formed using a nonphotosensitive organic or inorganic material. Further, a black pigment such as titanium black and carbon nitride or a dye may be dispersed in a material of the partition wall 265 by using a dispersant so that the partition wall 265 may be used as a black matrix. Preferably, an edge of the partition wall 265, where faces the first electrode, has a taper shape such that the curvature is continuously varied (FIG. 15B).

Subsequently, a buffer layer including an organic compound and a metal compound is formed to cover the first electrode 264 exposed from the partition wall 265. The buffer layer can be formed using the materials mentioned in the above embodiment modes. Next, a first hole transporting layer is formed. Thereafter, n pieces of light emitting layers and second hole transporting layers are alternately stacked. Over the stacked layers of the light emitting layers and the second hole transporting layers, a last light emitting layer is formed. Then, an electron transporting layer is stacked over the light emitting layer.

A second electrode 267 serving as a cathode is next formed. Thus, a light emitting device 293 including a multistacked structure including the organic light emitting layers and the carrier transporting layers made from an organic compound between the first electrode 264 and the second electrode 267 can be formed. By applying higher voltage to the first electrode than the second electrode, light emission can be obtained.

Afterwards, a silicon oxide film containing nitrogen is formed as a passivation film by plasma CVD. When using a silicon oxide film containing nitrogen, a silicon oxynitride film may be formed using SiH₄, N₂O, and NH₃ by plasma CVD, or a silicon oxynitride film may be formed using SiH₄ and N₂O by plasma CVD, or a silicon oxynitride film may be formed using a gas in which SiH₄ and N₂O are diluted with Ar, by plasma CVD.

Alternatively, as the passivation film, a hydrogenated silicon oxynitride film formed using SiH₄, N₂O, and H₂ may be used. The passivation film is, of course, not limited to a single layer structure, and it may have a single layer structure or a stacked structure of other insulating layer containing silicon. In addition, a multilayer film including a carbon nitride film and a silicon nitride film, a multilayer film including styrene polymer, a silicon nitride film, or a diamond like carbon film may be formed instead of the silicon oxide film containing nitrogen.

Subsequently, to protect the light emitting element from a substance which promotes deterioration of the light emitting element such as moisture, a display portion is sealed. When the display portion is sealed with a counter substrate, the counter substrate is adhered to the display portion with an insulating sealing material such that an external connection portion is exposed. A space between the counter substrate and the element substrate may be filled with an inert gas such as dried nitrogen. Alternatively, a sealing material may be applied over the entire surface of the pixel portion and then the counter substrate may be attached thereto. An ultraviolet curing resin or the like is preferably used as the sealing material. A drying agent or a particle for maintaining a constant gap between the substrates may be mixed in the sealing material. Subsequently, a flexible wiring substrate is attached to the external connection portion.

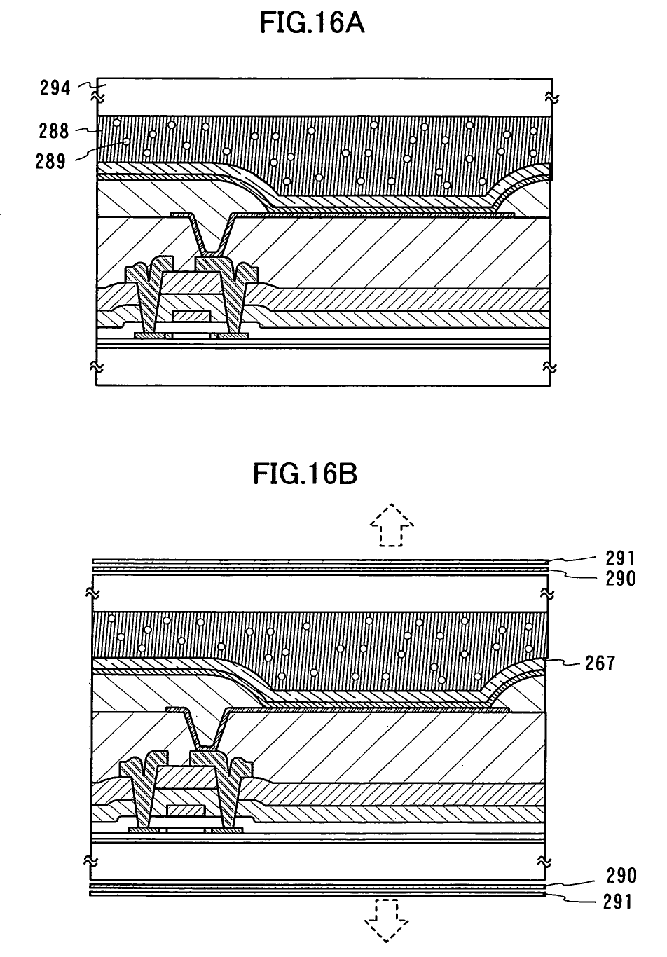

Examples of structures of a light emitting device formed above will be described with reference to FIGS. 16A and 16B. Further, portions having similar functions are sometimes denoted by same reference numerals, though they have different shapes so as to omit explanation. In this embodiment mode, the thin film transistor 270 having an LDD structure is connected to the light emitting device 293 through the connection portion 261a.

FIG. 16A shows a structure where the first electrode 264 is formed using a conductive film having a light transmitting property, and light generated in the light emitting stacked body 266 is emitted toward the substrate 250. Further, reference numeral 294 represents a counter substrate. After forming the light emitting device 293 over the substrate 250, the counter substrate is firmly attached to the substrate 250 using a sealing material or the like. A space between the counter substrate 294 and the light emitting device 293 is filled with a resin 288 having a light transmitting property or the like to seal the light emitting element. Accordingly, the light emitting device 293 can be prevented from being deteriorated by moisture or the like. Preferably, the resin 288 has a hygroscopic property. More preferably, to prevent the adverse influence of moisture, a drying agent 289 with a high light transmitting property is dispersed in the resin 288.

FIG. 16B shows a structure where both the first electrode 264 and the second electrode 267 are formed using conductive films having light transmitting properties and light can be emitted toward both the substrate 250 and the counter substrate 294. In this structure, by providing polarizing plates 290 outside of the substrate 250 and the counter substrate 294, a screen can be prevented from being transparent, thereby improving visibility. Protection films 291 may be provided outside of the polarizing plates 290.

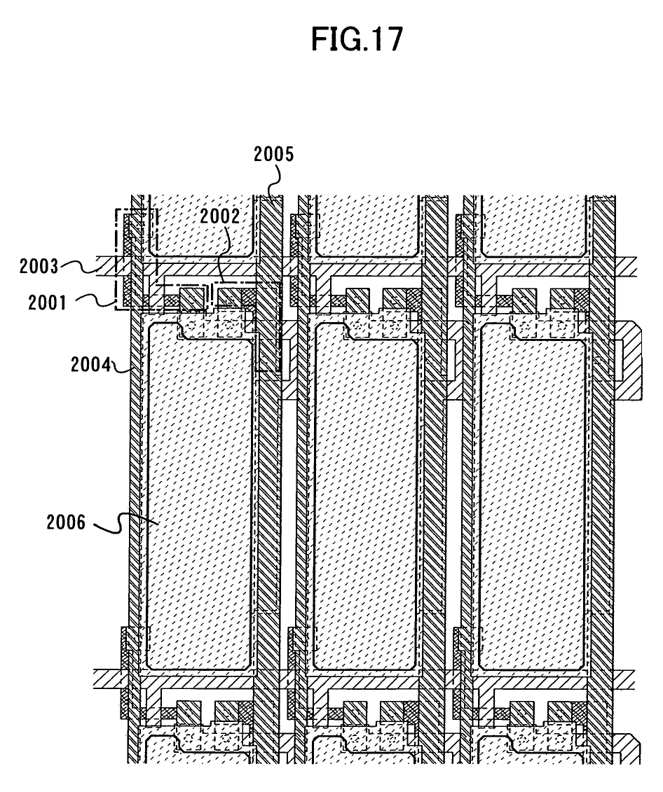

Further, arrangements of a transistor, a light emitting device, and the like are not particularly limited. For example, they can be arranged as shown in a top view of FIG. 17. In FIG. 17, a first electrode of a first transistor 2001 is connected to a source signal line 2004 and a second electrode is connected to a gate electrode of a second transistor 2002. A first electrode of the second transistor is connected to a power supply line 2005, and a second electrode of the second transistor is connected to an electrode 2006 of a light emitting element. A part of a gate signal line 2003 serves as a gate electrode of the first transistor 2001.

The light emitting device according to the present invention with a display function may employ either analog video signals or digital video signals. When using the digital video signals, light emitting display devices are classified into one in which the video signals use voltage and one in which the video signals use current. When light emitting devices emit light, video signals input in pixels are classified into one at constant voltage and one at constant current. The video signals at constant voltage include one in which constant voltage is applied to a light emitting device and one in which constant current flows through a light emitting device. The video signals at constant current include one in which constant voltage is applied to a light emitting device and one in which constant current flows though a light emitting device. The case where constant voltage is applied to a light emitting device indicates a constant voltage drive whereas the case where constant current flows though a light emitting device indicates a constant current drive. In the constant current drive, constant current flows regardless of the change in resistance of a light emitting device. The light emitting device of the invention and a method for driving the light emitting device may use either a driving method utilizing voltage of video signals or a driving method utilizing current of video signals. Furthermore, either the constant voltage drive or the constant current drive may be used.

The present embodiment mode can be implemented by being freely combined with any structure of the above described embodiment modes.

### Embodiment Mode 6

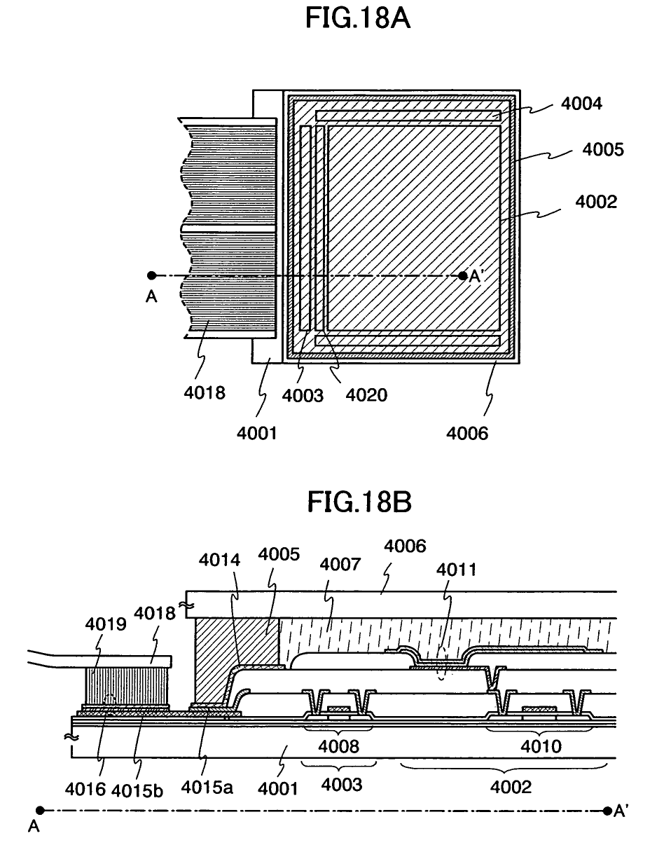

An outer appearance of a panel which is a light emitting device of the present invention, will be described in this embodiment mode with reference to FIGS. 18A and 18B. FIG. 18A is a top view of a panel in which a transistor and a light emitting device formed over a substrate are sealed with a sealing material that is formed between the substrate and a counter substrate 4006. FIG. 18B is a cross sectional view of FIG. 18A. The light emitting device mounted on this panel has a structure as shown in Embodiment Mode 5.

A sealing material 4005 is provided so as to surround a pixel portion 4002, a signal line driver circuit 4003, and a scanning line driver circuit 4004 that are provided over a substrate 4001. The counter substrate 4006 is provided over the pixel portion 4002, the signal line driver circuit 4003, and the scanning line driver circuit 4004. Thus, the pixel portion 4002, the signal line driver circuit 4003, and the scanning line driver circuit 4004 are hermetically sealed with the substrate 4001, the sealing material 4005, and the counter substrate 4006 along with a filler 4007.

The pixel portion 4002, the signal line driver circuit 4003, and the scanning line driver circuit 4004, which are provided over the substrate 4001, have a plurality of thin film transistors. In FIG. 18B, a thin film transistor 4008 included in the signal line driver circuit 4003 and a thin film transistor 4010 included in the pixel portion 4002 are shown.

Further, a light emitting device 4011 is electrically connected to the thin film transistor 4010. The light emitting device 4011 has a structure in which an anode; a hole transporting layer; light emitting layers and second electron transporting layers are alternately stacked; another light emitting layer; a first electron transporting layer; and a cathode are formed.

Also, a leading wiring 4014 corresponds to a wiring for supplying signals or power supply voltage to the pixel portion 4002, the signal line driver circuit 4003, and the scanning line driver circuit 4004. The leading wiring 4014 is connected to a connection terminal 4016 through a leading wiring 4015a and a leading wiring 4015b. The connection terminal 4016 is electrically connected to a terminal included in a flexible printed circuit (FPC) 4018 through an anisotropic conductive film 4019.

Further, as the filler 4007, an ultraviolet curing resin or a heat curing resin can be used in addition to an inert gas such as nitrogen and argon. For example, polyvinyl chloride, acrylic, polyimide, an epoxy resin, a silicon resin, polyvinyl butyral, or ethylene vinylene acetate can be used.

Furthermore, the present invention includes a panel in which a pixel portion having a light emitting device is formed and a module in which an IC is mounted on the panel.

The present embodiment mode can be implemented by being freely combined with any structure of the above described embodiment modes.

### Embodiment Mode 7

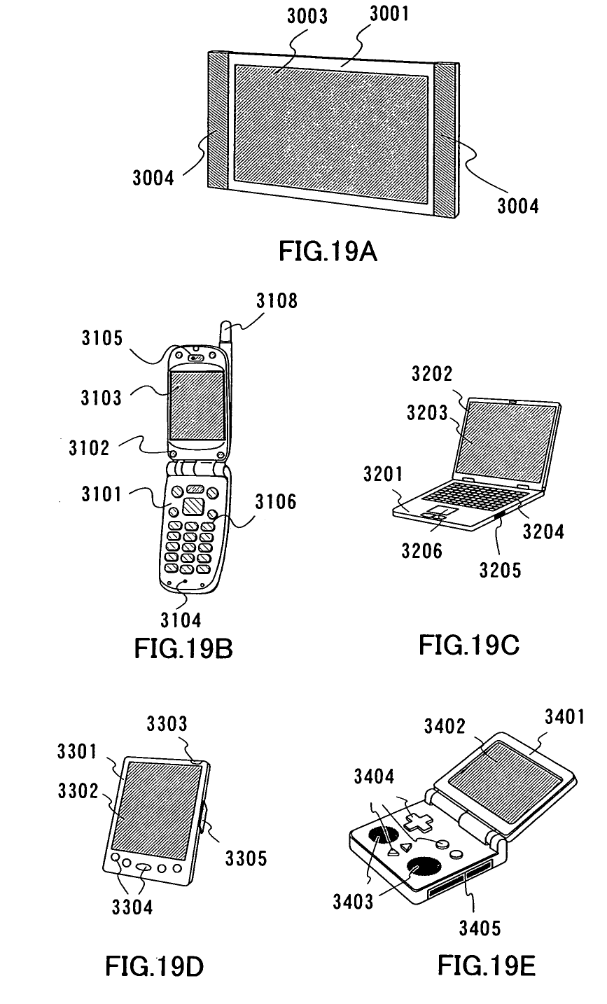

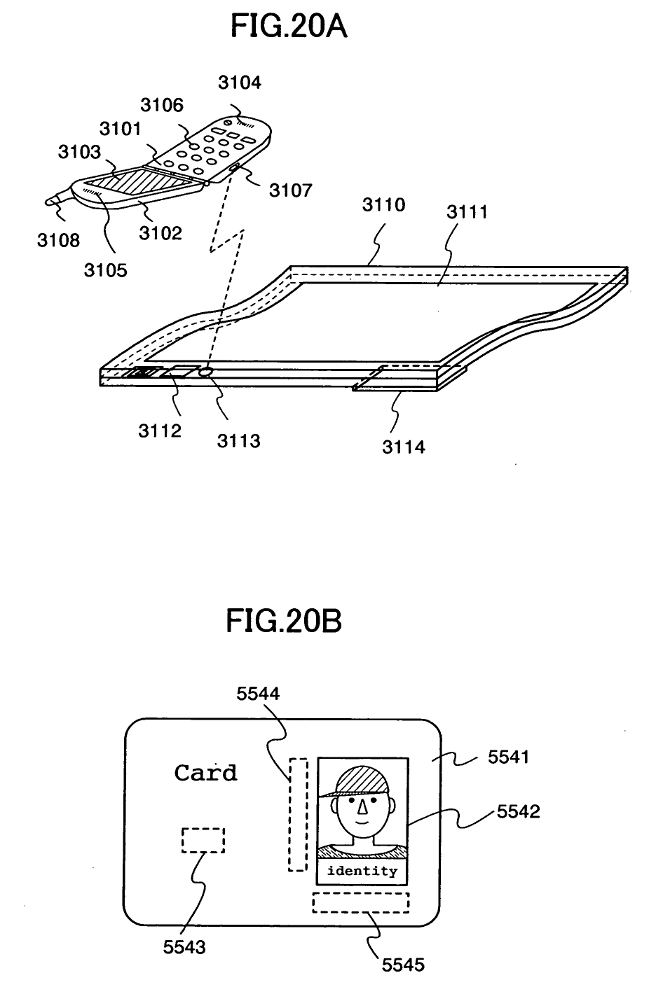

As electronic appliances having light emitting devices according to the present invention mounted with modules as shown in the above embodiment modes, a camera such as a video camera and a digital camera; a goggle type display (a head mounted display); a navigation system; an audio reproducing device (e.g., a car audio component); a computer; a game machine; a portable information terminal (e.g., a mobile computer, a mobile phone, a portable game machine, an electronic book, and the like); an image reproducing device equipped with a recording medium (concretely, a device having a display that can reproduce a recording medium such as a digital versatile disc (DVD) and can display an image thereof); and the like can be given. Specific examples of these electronic appliances are shown in FIGS. 19A to 19E, and FIGS. 20A and 20B.

FIG. 19A shows a monitor for a television receiver, a personal computer, or the like, including a housing 3001, a display portion 3003, speakers 3004, and the like. An active matrix display device is provided in the display portion 3003. Each pixel of the display portion 3003 includes a light emitting device having a multistacked structure of the present invention and a TFT. By using the light emitting device of the present invention, a television having high light emitting efficiency along with less deterioration in characteristic can be obtained.

FIG. 19B shows a mobile phone, including a main body 3101, a housing 3102, a display portion 3103, an audio input portion 3104, an audio output portion 3105, operation keys 3106, an antenna 3108, and the like. An active matrix display device is provided in the display portion 3103. Each pixel of the display portion 3103 includes a light emitting device having a multistacked structure of the present invention and a TFT. By using the light emitting device of the present invention, a mobile phone having high light emitting efficiency along with less deterioration in characteristic can be obtained.

FIG. 19C shows a computer, including a main body 3201, a housing 3202, a display portion 3203, a keyboard 3204, an external connection port 3205, a pointing mouse 3206, and the like. An active matrix display device is provided in the display portion 3203. Each pixel of the display portion 3203 includes a light emitting device having a multistacked structure of the present invention and a TFT. By using the light emitting device of the present invention, a computer having high light emitting efficiency along with less deterioration in characteristic can be obtained.

FIG. 19D shows a mobile computer, including a main body 3301, a display portion 3302, a switch 3303, operation keys 3304, an infrared port 3305, and the like. An active matrix display device is provided in the display portion 3302. Each pixel of the display portion 3302 includes a light emitting device having a multistacked structure of the present invention and a TFT. By using the light emitting device of the present invention, a mobile computer having high light emitting efficiency along with less deterioration in characteristic can be obtained.

FIG. 19E shows a portable game machine, including a housing 3401, a display portion 3402, speaker portions 3403, operation keys 3404, a recording medium insert portion 3405, and the like. An active matrix display device is provided in the display portion 3402. Each pixel of the display portion 3402 includes a light emitting device having a multistacked structure of the present invention and a TFT. By using the light emitting device of the present invention, a portable game machine having high light emitting efficiency along with less deterioration in characteristic can be obtained.

FIG. 20A shows a flexible display, including a main body 3110, a pixel portion 3111, a driver IC 3112, a receiving apparatus 3113, a film buttery 3114, and the like. The receiving apparatus 3113 can receive a signal from an infrared communication port 3107 of the above described mobile phone. An active matrix display device is provided in the pixel portion 3111. Each pixel of the pixel portion 3111 includes a light emitting device having a multistacked structure of the present invention and a TFT. By using the light emitting device of the present invention, a flexible display having high light emitting efficiency along with less deterioration in characteristic can be obtained.

FIG. 20B shows an ID card manufactured according to the present invention, including a supporting body 5541, a display portion 5542, an integrated circuit chip 5543 incorporated in the supporting body 5541, and the like.

An active matrix display device is provided in the display portion 5542. Each pixel of the display portion 5542 includes a light emitting device having a multistacked structure of the present invention and a TFT. By using the light emitting device of the present invention, an ID card having high light emitting efficiency along with less deterioration in characteristic can be obtained.

As set forth above, an application range of the present invention is extremely wide, and the present invention can be applied to electronic appliances in all fields.

This application is based on Japanese Patent Application Serial No. 2005-130956 filed in Japan Patent Office on Apr. 28, in 2005, the entire contents of which are hereby incorporated by reference.

What is claimed is:

1. A light emitting device comprising:
a substrate;
an anode;
a cathode facing the anode;
light emitting layers each comprising an organic compound and being provided between the anode and the cathode; and
hole transporting layers each comprising an organic compound,
wherein each of the light emitting layers and each of the hole transporting layers are alternately stacked,
wherein a thickness of each of the hole transporting layers is thinner than a thickness of each of the light emitting layers, wherein each of the light emitting layers has an electron transporting property.

2. A light emitting device according to claim 1, wherein 2 to n (n is a positive integer) pieces of the light emitting layers and the hole transporting layers are alternately stacked.

3. A light emitting device according to claim 1, wherein the thickness of each of the hole transporting layers is 1 to 5 nm, and the thickness of each of the light emitting layers is 5 to 20 nm.

4. A light emitting device according to claim 1, wherein an absolute value of an energy difference between a LUMO level of each of the light emitting layers and a vacuum level is larger than an absolute value of an energy difference between a LUMO level of each of the hole transporting layers and the vacuum level, and
wherein an absolute value between a HOMO level of each of the light emitting layers and the vacuum level is larger than an absolute value of an energy difference between a HOMO level of each of the hole transporting layers and the vacuum level.

5. A light emitting device according to claim 1, wherein the LUMO level of each of the light emitting layers is lower than the LUMO level of each of the hole transporting layers, and
wherein the HOMO level of each of the light emitting layers is lower than the HOMO level of each of the hole transporting layers.

6. A light emitting device according to claim 1, wherein a buffer layer including an organic compound and a metal compound is provided to be in contact with the anode.

7. A light emitting device comprising:
a substrate;
an anode;
a cathode facing the anode;
light emitting layers each comprising an organic compound and being provided between the anode and the cathode; and
electron transporting layers each comprising an organic compound,
wherein each of the light emitting layers and each of the electron transporting layers are alternately stacked,
wherein a thickness of each of the electron transporting layers is thinner than a thickness of each of the light emitting layers,
wherein each of the light emitting layers has a hole transporting property.

8. A light emitting device according to claim 7, wherein 2 to n (n is a positive integer) pieces of the light emitting layers and the electron transporting layers are alternately stacked.

9. A light emitting device according to claim 7, wherein the thickness of each of the electron transporting layers is 1 to 5 nm, and the thickness of each of the light emitting layers is 5 to 20 nm.

10. A light emitting device according to claim 7,
wherein an absolute value of an energy difference between a LUMO level of each of the light emitting layers and a vacuum level is smaller than an absolute value of an energy difference between a LUMO level of each of the electron transporting layers and the vacuum level, and
wherein an absolute value between a HOMO level of each of the light emitting layers and the vacuum level is smaller than an absolute value of an energy difference between a HOMO level of each of the electron transporting layers and the vacuum level.

11. A light emitting device according to claim 7,
wherein the LUMO level of each of the light emitting layers is higher than the LUMO level of each of the electron transporting layers, and
wherein the HOMO level of each of the light emitting layers is higher than the HOMO level of each of the electron transporting layers.

12. A light emitting device according to claim 7, wherein a buffer layer including an organic compound and a metal compound is provided to be in contact with the anode.

13. A light emitting device comprising:
a substrate;
an anode;
a cathode facing the anode;
light emitting layers each comprising an organic compound and being provided between the anode and cathode;
a first hole transporting layer comprising an organic compound; and
second hole transporting layers each comprising an organic compound,
wherein the first hole transporting layer is formed over the anode,
wherein each of the light emitting layers and each of the second hole transporting layers are alternately stacked over the first hole transporting layer,
wherein a thickness of each of the second hole transporting layers is thinner than a thickness of each of the light emitting layers, and
wherein each of the light emitting layers has an electron transporting property.

14. A light emitting device according to claim 13, wherein 2 to n (n is a positive integer) pieces of the light emitting layers and the second hole transporting layers are alternately stacked.

15. A light emitting device according to claim 13, wherein the thickness of each of the second hole transporting layers is 1 to 5 nm, and the thickness of each of the light emitting layers is 5 to 20 nm.

16. A light emitting device according to claim 13,
wherein an absolute value of an energy difference between a LUMO level of each of the light emitting layers and a vacuum level is larger than an absolute value of an energy difference between a LUMO level of each of the second hole transporting layers and the vacuum level, and
wherein an absolute value between a HOMO level of each of the light emitting layers and the vacuum level is larger than an absolute value of an energy difference between a HOMO level of each of the second hole transporting layers and the vacuum level.

17. A light emitting device according to claim 13,
wherein the LUMO level of each of the light emitting layers is lower than the LUMO level of each of the second hole transporting layers, and
wherein the HOMO level of each of the light emitting layers is lower than the HOMO level of the each of second hole transporting layers.

18. A light emitting device according to claim 13, wherein an absolute value of an energy difference between a HOMO level of the first hole transporting layer and the HOMO level of each of the light emitting layers is smaller than an absolute value of an energy difference between the HOMO level of each of the second hole transporting layers and the HOMO level of each of the light emitting layers.

19. A light emitting device according to claim 13, wherein an absolute value of an energy difference between work function of the anode and the HOMO level of the first hole transporting layer is smaller than an absolute value of an energy difference between the HOMO level of each of the second hole transporting layers and the HOMO level of each of the light emitting layers.

20. A light emitting device according to claim 13, wherein a buffer layer including an organic compound and a metal compound is provided between the first hole transporting layer and the anode.

21. A light emitting device comprising:
a substrate;
an anode;
a cathode facing the anode;
light emitting layers each comprising an organic compound and being provided between the anode and cathode;
a first electron transporting layer comprising an organic compound; and
second electron transporting layers each comprising an organic compound,
wherein each of the light emitting layers and each of the second electron transporting layers are alternately stacked,
wherein the first electron transporting layer is formed over the alternately stacked layer,
wherein the cathode is formed over the first electron transporting layer,
wherein a thickness of each of the second electron transporting layers is thinner than a thickness of each of the light emitting layers, and
wherein each of the light emitting layers has a hole transporting property.

22. A light emitting device according to claim 21, wherein 2 to n (n is a positive integer) pieces of the light emitting layers and the second electron transporting layers are alternately stacked.

23. A light emitting device according to claim 21, wherein the thickness of each of the second electron transporting layers is 1 to 5 nm, and the thickness of each of the light emitting layers is 5 to 20 nm.

24. A light emitting device according to claim 21,
wherein an absolute value of an energy difference between a LUMO level of each of the light emitting layers and a vacuum level is smaller than an absolute value of an energy difference between a LUMO level of each of the second electron transporting layers and the vacuum level, and
wherein an absolute value between a HOMO level of each of the light emitting layers and the vacuum level is smaller than an absolute value of an energy difference between a HOMO level of each of the second electron transporting layers and the vacuum level.

25. A light emitting device according to claim 21,
wherein the LUMO level of each of the light emitting layers is higher than the LUMO level of each of the second electron transporting layers, and
wherein the HOMO level of each of the light emitting layers is higher than the HOMO level of each of the second electron transporting layers.

26. A light emitting device according to claim 21, wherein an absolute value of an energy difference between a HOMO level of the first electron transporting layer and the HOMO level of each of the light emitting layers is smaller than an absolute value of an energy difference between the HOMO level of each of the second electron transporting layers and the HOMO level of each of the light emitting layers.

27. A light emitting device according to claim 21, wherein an absolute value of an energy difference between work function of the anode and the HOMO level of the first electron transporting layer is smaller than an absolute value of an energy difference between the HOMO level of each of the second electron transporting layers and the HOMO level of each of the light emitting layers.

28. A light emitting device according to claim 21, wherein a buffer layer including an organic compound and a metal compound is provided between the alternately stacked layer and the anode.

29. A method for manufacturing a light emitting device comprising a substrate, an anode, a cathode facing the anode, light emitting layers each comprising an organic compound and being provided between the anode and the cathode, and carrier transporting layers each comprising an organic compound, wherein each of the light emitting layers and each of the carrier transporting layers are alternately stacked, a thickness of each of the carrier transporting layers is thinner than a thickness of each of the light emitting layer,
wherein the substrate is provided over an evaporation source of a carrier transporting material and an evaporation source of a light emitting material,
wherein a first shutter, which is openable and closable, is provided between the evaporation source of the carrier transporting material and the substrate,
wherein a second shutter, which is openable and closable, is provided between the evaporation source of the light emitting material and the substrate, and
wherein each of the light emitting layers and each of the carrier transporting layers are alternately stacked by opening and closing the first and second shutters.

30. A method for manufacturing a light emitting device according to claim 29,
wherein when the first shutter is opened, the second shutter is closed and the carrier transporting material is evaporated over the substrate, and
wherein when the second shutter is opened, the first shutter is closed and the light emitting material is evaporated over the substrate so that each of the light emitting layers and each of the carrier transporting layers are alternately stacked.

31. A method for manufacturing a light emitting device according to claim 29,
wherein each of the light emitting layers and each of the carrier transporting layers are alternately stacked by opening and closing the first and second shutters and by controlling an evaporation rate of the light emitting material and an evaporation rate of the carrier transporting material.

32. A method for manufacturing a light emitting device comprising a substrate, an anode, a cathode facing the anode, light emitting layers each comprising an organic compound and being provided between the anode and the cathode, and carrier transporting layers each comprising an organic compound, wherein each of the light emitting layers and each of the carrier transporting layers are alternately stacked, a thickness of each of the carrier transporting layers is thinner than a thickness of each of the light emitting layers,
wherein the substrate is provided over a first rotating plate,
wherein the first rotating plate is provided over an evaporation source of a light emitting material and an evaporation source of a carrier transporting material,
wherein each of the light emitting layers and each of the carrier transporting layers are alternately stacked by rotating the first rotating plate and changing a distance between the evaporation source of the light emitting material and the substrate and a distance between the evaporation source of the carrier transporting material and the substrate.

33. A method for manufacturing a light emitting device according to claim 32,
wherein when by rotating the first rotating plate, the distance between the evaporation source of the light emitting material and the substrate is shorter than the distance between the evaporation source of the carrier transporting material and the substrate, a larger amount of the light emitting material is evaporated over the substrate than the carrier transporting material so as to form each of the light emitting layers, and
wherein when the distance between the evaporation source of the carrier transporting material and the substrate is shorter than the distance between the evaporation source of the light emitting material and the substrate, a larger amount of the carrier transporting material is evaporated over the substrate than the light emitting material so as to form each of the carrier transporting layers.

34. A method for manufacturing a light emitting device according to claim 32, wherein each of the light emitting layers and each of the carrier transporting layers are alternately stacked by controlling an evaporation rate of the light emitting material and an evaporation rate of the carrier transporting material.

35. A method for manufacturing a light emitting device according to claim 32,
wherein a shutter, which is openable and closable, is provided between the carrier transporting material and the substrate, and
wherein by controlling rotation of the first rotating plate and opening and closing of the shutter, each of the light emitting layers and each of the carrier transporting layers are alternately stacked.

36. A method for manufacturing a light emitting device according to claim 32,
wherein a second rotating plate is provided over the first rotating plate,
wherein the substrate is provided over the second rotating plate; and
wherein the first rotating plate and second rotating plate have difference central axes from each other and rotate independently.

37. A method for manufacturing a light emitting device comprising a substrate, an anode, a cathode facing the anode, light emitting layers each comprising an organic compound and being provided between the anode and the cathode, and carrier transporting layers each comprising an organic compound, wherein each of the light emitting layers and each of the carrier transporting layers are alternately stacked, a thickness of each of the carrier transporting layers is thinner than a thickness of each of the light emitting layers,
wherein the substrate is provided over an evaporation source of a light emitting material and an evaporation source of a carrier transporting material,
wherein a first mask, which is rotatable, is provided between the evaporation source of the light emitting material and the substrate,
wherein a second mask, which is rotatable, is provided between the evaporation source of the carrier transporting material and the substrate, and
wherein each of the light emitting layers and each of the carrier transporting layers are alternately stacked by controlling rotation of the first and second masks.

38. A method for manufacturing a light emitting device according to claim 37 wherein a hole or a slit is provided in each of the first and second masks.

39. A method for manufacturing a light emitting device according to claim 37,
wherein a hole or a slit is provided in each of the first and second masks,
wherein when the hole or slit of the first mask is positioned between the evaporation source of the light emitting material and the substrate while the hole or slit of the second mask is not positioned between the evaporation source of the carrier transporting material and the substrate, the light emitting material is evaporated over the substrate, and
wherein when the hole or slit of the second mask is positioned between the evaporation source of the carrier transporting material and the substrate while the hole or slit of the first mask is not positioned between the evaporation source of the light emitting material and the substrate, the carrier transporting material is evaporated over the substrate.

40. A method for manufacturing a light emitting device according to claim 37, wherein each of the light emitting layers and each of the carrier transporting layers are alternately stacked by controlling an evaporation rate of the light emitting material and an evaporation rate of the carrier transporting material.
